(19) United States
(12) Patent Application Publication
(10) Pub. No.: US 2024/0146031 A1
(43) Pub. Date: May 2, 2024

(54) SURFACE EMITTING LASER AND ELECTRONIC DEVICE

(71) Applicant: SONY GROUP CORPORATION, TOKYO (JP)

(72) Inventors: MICHINORI SHIOMI, TOKYO (JP); MASAYUKI TANAKA, TOKYO (JP); TOMOMASA WATANABE, TOKYO (JP); MIKIHIRO YOKOZEKI, TOKYO (JP)

(21) Appl. No.: 18/548,161

(22) PCT Filed: Jan. 21, 2022
(86) PCT No.: PCT/JP2022/002086

§ 371 Date: Aug. 28, 2023

(30) Foreign Application Priority Data
Mar. 3, 2021 (JP) 2021-033502

(51) Int. Cl. H01S 5/30; H01S 5/183

(52) U.S. Cl. CPC H01S 5/3095; H01S 5/18308; H01S 5/18369; H01S 5/3013

(57) ABSTRACT

The present technology provides a surface emitting laser capable of performing current confinement at least in a tunnel junction layer while suppressing the characteristic change of the tunnel junction layer.

The surface emitting laser according to the present technology includes: first and second reflectors; and a resonator disposed between the first and second reflectors, the resonator including an active layer and a tunnel junction layer, in which, in the resonator, a peripheral portion has higher resistance than a central portion at least in an entire region in a thickness direction of the tunnel junction layer. According to the surface emitting laser according to the present technology, it is possible to provide a surface emitting laser capable of performing current confinement at least in a tunnel junction layer while suppressing the characteristic change of the tunnel junction layer.

### TECHNICAL FIELD

The technology according to the present disclosure (hereinafter also referred to as “the present technology”) relates to a surface emitting laser and an electronic device.

### BACKGROUND ART

Conventionally, surface emitting lasers in which a resonator including an active layer is disposed between first and second multilayer film reflectors are known. Some surface emitting lasers are provided with a buried tunnel junction (BTJ) structure in a resonator (see, for example, Patent Document 1).

### CITATION LIST

### Patent Document

Patent Document 1: Japanese Patent Application Laid-Open No. 2006-508550

### SUMMARY OF THE INVENTION

### Problems To Be Solved by the Invention

However, in the conventional surface emitting laser, in order to form the BTJ structure, etching of the tunnel junction layer (TJ layer) and subsequent embedded regrowth are required, and the number of manufacturing steps is increased.

Therefore, a main object of the present technology is to provide a surface emitting laser that does not require etching of a tunnel junction layer (TJ layer) and subsequent embedded regrowth and can reduce the number of manufacturing steps.

### Solutions to Problems

The present technology provides a surface emitting laser including:
first and second reflectors; and
a resonator disposed between the first and second reflectors, the resonator including an active layer and a tunnel junction layer,
in which, in the resonator, a peripheral portion has higher resistance than a central portion at least in an entire region in a thickness direction of the tunnel junction layer.

The resonator may include a cladding layer between the tunnel junction layer and the active layer, and in the cladding layer, at least a peripheral portion of a portion on a side of the tunnel junction layer may have higher resistance than a central portion.

The cladding layer may be a p-type semiconductor layer.

The cladding layer may be constituted by a p-type InP-based compound semiconductor.

In the active layer, at least a peripheral portion of a portion on a side of the tunnel junction layer may have higher resistance than a central portion.

The resonator may include a cladding layer on a side of the active layer opposite to a side of the tunnel junction layer, and the cladding layer may have a lower resistance than a peripheral portion of the tunnel junction layer.

An electrode may be provided on the cladding layer.

The cladding layer may be an n-type semiconductor layer.

The cladding layer may be constituted by an n-type InP-based compound semiconductor.

The resonator may include a cladding layer on a side of the tunnel junction layer opposite to a side of the active layer, and the cladding layer may have a lower resistance than a peripheral portion of the tunnel junction layer.

An electrode may be provided on the cladding layer.

The cladding layer may be an n-type semiconductor layer.

The cladding layer may be constituted by an n-type InP compound semiconductor.

A peripheral portion of the resonator may be increased in resistance by ion implantation at least in an entire region in a thickness direction of the tunnel junction layer.

An impurity concentration in the ion implantation may be less than 1×10¹⁹ cm⁻³.

Impurity in the ion implantation may include at least one of H, B, C, or O.

The tunnel junction layer may include a p-type semiconductor region and an n-type semiconductor region, and each of the p-type semiconductor region and the n-type semiconductor region may be constituted by any of an InP-based compound semiconductor, an AlGaInAs-based compound semiconductor, and an AlGaInSbAs-based compound semiconductor.

The imaging device may further include a substrate disposed between the resonator and a reflector closer to the active layer than the tunnel junction layer among the first and second reflectors, and the reflector may be a concave multilayer film reflector.

The thermal conductivity of the substrate may be 40 W/m·K or more.

The present technology also provides an electronic device including the surface emitting laser.

### BRIEF DESCRIPTION OF DRAWINGS

FIG. 1 is a cross-sectional view of a surface emitting laser according to a first embodiment of the present technology.

FIG. 2 is a flowchart for explaining an example of a method for manufacturing the surface emitting laser of FIG. 1 and the like.

FIG. 3 is a flowchart for explaining an example of a first step (laminate generation process 1) in FIG. 2 and the like.

FIG. 4 is a cross-sectional view of a laminate generated by a laminate generation process 1.

FIG. 5 is a cross-sectional view illustrating a second step in FIG. 2.

FIG. 6 is a cross-sectional view illustrating a third step in FIG. 2.

FIG. 7 is a cross-sectional view illustrating a fourth step in FIG. 2.

FIG. 8 is a cross-sectional view illustrating a fifth step in FIG. 2.

FIG. 9 is a cross-sectional view illustrating a sixth step in FIG. 2.

FIG. 10 is a cross-sectional view illustrating a seventh step in FIG. 2.

FIG. 11 is a cross-sectional view illustrating an eighth step in FIG. 2.

FIG. 12 is a cross-sectional view illustrating a ninth step in FIG. 2.

FIG. 13 is a cross-sectional view illustrating a 10th step in FIG. 2.

FIG. 14 is a cross-sectional view illustrating a 11th step in FIG. 2.

FIG. 15 is a cross-sectional view illustrating a 12th step in FIG. 2.

FIG. 16 is a cross-sectional view illustrating a 13th step in FIG. 2.

FIG. 17 is a cross-sectional view illustrating a 14th step in FIG. 2.

FIG. 18 is a cross-sectional view illustrating a 15th step (before removal of residual wax) in FIG. 2.

FIG. 19 is a cross-sectional view illustrating a 15th step (after removal of residual wax) in FIG. 2.

FIG. 20 is a cross-sectional view illustrating a 16th step in FIG. 2.

FIG. 21 is a flowchart for explaining another example of the method for manufacturing the surface emitting laser of FIG. 1 and the like.

FIG. 22 is a cross-sectional view illustrating a second step in FIG. 21.

FIG. 23 is a cross-sectional view illustrating a third step in FIG. 21.

FIG. 24 is a cross-sectional view illustrating a fourth step in FIG. 21.

FIG. 25 is a cross-sectional view illustrating a fifth step in FIG. 21.

FIG. 26 is a cross-sectional view illustrating a sixth step in FIG. 21.

FIG. 27 is a cross-sectional view illustrating a seventh step in FIG. 21.

FIG. 28 is a cross-sectional view illustrating an eighth step in FIG. 21.

FIG. 29 is a cross-sectional view illustrating a ninth step in FIG. 21.

FIG. 30 is a cross-sectional view illustrating a 10th step in FIG. 21.

FIG. 31 is a cross-sectional view illustrating a 11th step in FIG. 21.

FIG. 32 is a cross-sectional view illustrating a 12th step in FIG. 21.

FIG. 33 is a cross-sectional view illustrating a 13th step in FIG. 21.

FIG. 34 is a cross-sectional view illustrating a 14th step in FIG. 21.

FIG. 35 is a cross-sectional view illustrating a 15th step (before removal of residual wax) in FIG. 21.

FIG. 36 is a cross-sectional view illustrating a 15th step (after removal of residual wax) in FIG. 21.

FIG. 37 is a cross-sectional view illustrating a 16th step in FIG. 21.

FIG. 38 is a cross-sectional view of a surface emitting laser according to Modification 1 of the first embodiment of the present technology.

FIG. 39 is a cross-sectional view of a surface emitting laser according to Modification 2 of the first embodiment of the present technology.

FIG. 40 is a cross-sectional view of a surface emitting laser according to Modification 3 of the first embodiment of the present technology.

FIG. 41 is a cross-sectional view of a surface emitting laser according to Modification 4 of the first embodiment of the present technology.

FIG. 42 is a cross-sectional view of a surface emitting laser according to Modification 5 of the first embodiment of the present technology.

FIG. 43 is a cross-sectional view of a surface emitting laser according to a second embodiment of the present technology.

FIG. 44 is a flowchart for explaining a laminate generation process 2.

FIG. 45 is a cross-sectional view of a laminate generated by a laminate generation process 2.

FIG. 46 is a cross-sectional view of a surface emitting laser according to Modification 1 of the second embodiment of the present technology.

FIG. 47 is a cross-sectional view of a surface emitting laser according to Modification 2 of the second embodiment of the present technology.

FIG. 48 is a flowchart for explaining a laminate generation process 3.

FIG. 49 is a cross-sectional view of a laminate generated by a laminate generation process 3.

FIG. 50 is a cross-sectional view of a surface emitting laser according to Modification 3 of the second embodiment of the present technology.

FIG. 51 is a cross-sectional view of a surface emitting laser according to Modification 4 of the second embodiment of the present technology.

FIG. 52 is a cross-sectional view of a surface emitting laser according to a third embodiment of the present technology.

FIG. 53 is a flowchart for explaining the method for manufacturing the surface emitting laser of FIG. 52 and the like.

FIG. 54 is a diagram illustrating an application example of the surface emitting laser according to the present technology to a distance measuring device.

FIG. 55 is a block diagram illustrating an example of a schematic configuration of a vehicle control system.

FIG. 56 is an explanatory diagram illustrating an example of installation positions of distance measuring devices.

### MODE FOR CARRYING OUT THE INVENTION

Hereinafter, preferred embodiments of the present technology will be described in detail with reference to the accompanying drawings. Note that, in the present specification and drawings, components having substantially the same functional configuration are denoted by the same reference numerals to avoid the description from being redundant. The embodiments described below illustrate representative embodiments of the present technology, and the scope of the present technology is not to be narrowly interpreted according to these embodiments. In the present specification, even in a case where it is described that a surface emitting laser and an electronic device according to the present technology exhibits a plurality of effects, it is sufficient if the surface emitting laser and the electronic device according to the present technology exhibits at least one effect. The effects described herein are merely examples and are not limited, and other effects may be provided.

Furthermore, the description will be given in the following order.
1. Introduction
2. Surface Emitting Laser According to First Embodiment of Present Technology
(1) Configuration of Surface Emitting Laser
(2) Operation of Surface Emitting Laser
(3) First Example of Method for Manufacturing Surface Emitting Laser
(4) Second Example of Method for Manufacturing Surface Emitting Laser
(5) Effects of Surface Emitting Laser and Method for Manufacturing the Same
3. Surface Emitting Lasers According to Modifications 1 to
5 of First Embodiment of Present Technology
4. Surface Emitting Laser According to Second Embodiment of Present Technology
(1) Configuration of Surface Emitting Laser
(2) Method for Manufacturing Surface Emitting Laser
(3) Effects of Surface Emitting Laser and Method for Manufacturing the Same
5. Surface Emitting Lasers According to Modifications 1 to
4 of Second Embodiment of Present Technology
6. Surface Emitting Laser According to Third Embodiment of Present Technology
7. Modification of Present Technology
8. Application Example to Electronic Device
9. Example in Which Surface Emitting Laser Is Applied to Distance Measuring Device
10. Example in Which Distance Measuring Device Is Mounted on Mobile Body

### 1. Introduction

In recent years, infrared-surface emitting lasers used for 3D sensing and face authentication have been developed. At present, for example, a 940 nm band is mainly used as an oscillation wavelength in an infrared-surface emitting laser, but a further longer wavelength is desired in the future. In particular, for example, the 1.4 pm band is an eye safe band in which the damage threshold to the eye greatly increases, and has an advantage that noise at the time of sensing can be suppressed low because the intensity of sunlight is low.

On the other hand, an InP-based surface emitting laser suitable for a long wavelength of, for example, 1.3 pm or more as an oscillation wavelength has a problem that it is difficult to produce a current confinement structure by oxidation of an AlAs layer used in, for example, a GaAs-based surface emitting laser. For this reason, in the InP-based surface emitting laser, a buried tunnel junction (BTJ) structure is frequently used as a current confinement structure, but in this BTJ structure, etching of a tunnel junction layer (TJ layer) and subsequent embedded regrowth are required, and the number of steps increases.

Therefore, the inventors have developed a surface emitting laser represented by, for example, an InP-based surface emitting laser having a current confinement structure, which can be manufactured with a small number of steps without requiring both etching and subsequent embedded regrowth.

### 2. Surface Emitting Laser According to First Embodiment of Present Technology

### (1) Configuration of Surface Emitting Laser

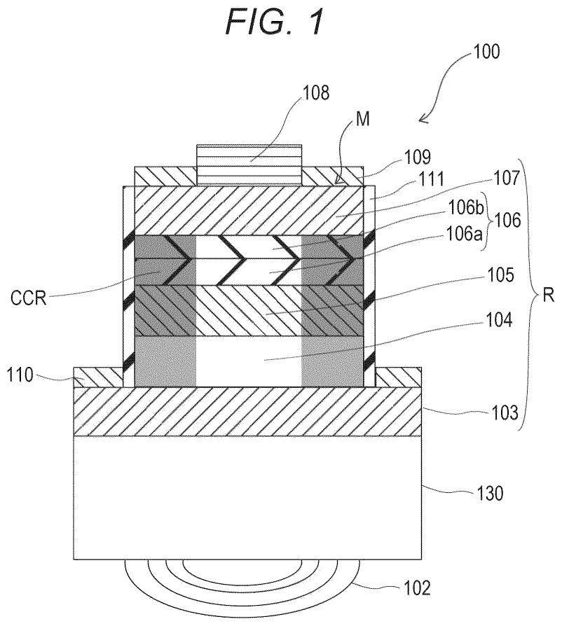

FIG. 1 is a cross-sectional view illustrating a configuration of a surface emitting laser 100 according to a first embodiment of the present technology. Hereinafter, for the sake of convenience, the upper part in the cross-sectional view of FIG. 1 and the like will be described as an upper side, and the lower part in the cross-sectional view of FIG. 1 and the like will be described as a lower side.

As an example, as illustrated in FIG. 1, the surface emitting laser 100 includes first and second reflectors 108 and 102 and a resonator R disposed between the first and second reflectors 108 and 102.

The surface emitting laser 100 is driven by, for example, a laser driver.

In the surface emitting laser 100, as an example, the resonator R and the first reflector 108 are arranged in this order from the substrate 130 side on the front surface (upper surface) of the substrate 130, and the second reflector 102 is provided on the back surface (lower surface) of the substrate 130.

In the surface emitting laser 100, as an example, a mesa M including a part (upper portion) of the resonator R is formed on the substrate 130. The mesa M has, for example, a substantially cylindrical shape, but may have another shape such as a substantially elliptical columnar shape, a polygonal columnar shape, a truncated cone shape, an elliptical frustum shape, or a polygonal frustum shape. A height direction of the mesa M substantially coincides with a stacking direction (vertical direction) of each of the constituent layers of the surface emitting laser 100.

As an example, the surface emitting laser 100 emits light from the upper surface (emission surface) of the first reflector 108 provided at the top portion of the mesa M. That is, as an example, the surface emitting laser 100 is a front surface emitting type surface emitting laser.

### [Substrate]

The substrate 130 is disposed between the resonator R and the second reflector 102 which is a reflector closer to an active layer 104 described later than a tunnel junction layer 106 among the first and second reflectors 108 and 102. Since the substrate 130 is a substrate for forming the second reflector 102 when the surface emitting laser 100 is manufactured as described later, it is also referred to as a “reflector forming substrate 130”.

The substrate 130 is, for example, a semiconductor substrate such as a GaAs substrate, a Si substrate, or a SiC substrate. The thermal conductivity of the substrate 130 is preferably, for example, 40 W/m·K or more.

### [First Reflector]

The first reflector 108 is, for example, a dielectric multilayer film reflector. As a material of the dielectric multilayer film reflector, for example, SiO₂, TiO₂, Ta₂O₅, a-Si, Al₂O₃, or the like can be used.

### [Second Reflector]

As an example, the second reflector 102 is a concave dielectric multilayer film reflector, and is provided on the back surface (lower surface) of the substrate 130. As a material of the dielectric multilayer film reflector, for example, SiO₂, TiO₂, Ta₂O₅, a-Si, Al₂O₃, or the like can be used. The reflectance of the second reflector 102 is set slightly higher than that of the first reflector 108.

### [Resonator]

The resonator R includes the active layer 104 and the tunnel junction layer 106. Here, the active layer 104 is disposed on the substrate 130 side (lower side) of the tunnel junction layer 106. That is, the tunnel junction layer 106 is disposed on the upstream side of a current path from the anode electrode 109 to the cathode electrode 110 described later with respect to the active layer 104. Further, the resonator R includes a first cladding layer 105 between the tunnel junction layer 106 and the active layer 104. Further, the resonator R includes a second cladding layer 103 on the side of the active layer 104 opposite to the tunnel junction layer 106 side. Further, the resonator R includes a third cladding layer 107 on the side opposite to the active layer 104 side of the tunnel junction layer 106.

That is, in the resonator R, the second cladding layer 103, the active layer 104, the first cladding layer 105, the tunnel junction layer 106, and the third cladding layer 107 are arranged in this order from the substrate 130 side (lower side).

As an example, the active layer 105 has a quantum well structure including a barrier layer constituted by an AlGaInAs-based compound semiconductor and a quantum well layer. This quantum well structure may be a single quantum well structure (QW structure) or a multiple quantum well structure (MQW structure).

The tunnel junction layer 106 includes a p-type semiconductor region 106a and an n-type semiconductor region 106b arranged in contact with each other. Here, the p-type semiconductor region 106a is arranged on the substrate 130 side (lower side) of the n-type semiconductor region 106b.

The p-type semiconductor region 106a is constituted by, for example, a p-type AlGaInAs-based compound semiconductor highly doped with C, Mg, or Zn. The n-type semiconductor region 106b is constituted by, for example, an InP-based compound semiconductor or an AlGaInAs-based compound semiconductor highly doped with Si.

The first cladding layer 105 is, for example, a p-type semiconductor layer, and is constituted by, for example, a p-type InP-based compound semiconductor.

The second cladding layer 103 is, for example, an n-type semiconductor layer, and is constituted by, for example, an n-type InP-based compound semiconductor. On the second cladding layer 103, as an example, a cathode electrode 110 having a circular shape (for example, a ring shape) is provided so as to surround the mesa M via an insulating film 111 provided on a side surface of the mesa M. The insulating film 111 is constituted by a dielectric such as SiO₂, SiN, or SiON. The cathode electrode 110 is constituted by, for example, Au/Ni/AuGe, Au/Pt/Ti, or the like. The cathode electrode 110 is electrically connected to, for example, a cathode (negative electrode) of the laser driver.

The third cladding layer 107 is, for example, an n-type semiconductor layer, and is constituted by, for example, an n-type InP-based compound semiconductor. As an example, the first reflector 108 is provided on the central portion of the third cladding layer 107, and the anode electrode 109 having a circular shape (ring shape) is provided on the peripheral portion so as to surround the first reflector 108. The anode electrode 109 is constituted by, for example, Au/Ni/AuGe, Au/Pt/Ti, or the like. The anode electrode 109 is electrically connected to, for example, an anode (positive electrode) of the laser driver.

In the resonator R, a part (for example, an intermediate portion) in the thickness direction (stacking direction, vertical direction, height direction of mesa M) of the peripheral portion is a current confinement region CCR (a portion colored in gray in FIG. 1) having higher resistance than the central portion surrounded by the part. That is, the current confinement region CCR is a high resistance region (region having low carrier conductivity), and a region surrounded by the current confinement region CCR is a low resistance region (region having high carrier conductivity).

More specifically, in the resonator R, the peripheral portion has higher resistance than the central portion in the entire region in the thickness direction of the tunnel junction layer 106. Furthermore, in the resonator R, the peripheral portion has higher resistance than the central portion in the entire region in the thickness direction of the first cladding layer 105. Furthermore, in the resonator R, the peripheral portion has higher resistance than the central portion in the entire region in the thickness direction of the active layer 104. Furthermore, in the resonator R, the central portion and the peripheral portion of the second cladding layer 103 have lower resistance than the peripheral portion of the tunnel junction layer 106. Furthermore, in the resonator R, the third cladding layer 107 has lower resistance than the peripheral portion of the tunnel junction layer 106.

That is, here, the current confinement region CCR includes a peripheral portion of the tunnel junction layer 106, a peripheral portion of the first cladding layer 105, and a peripheral portion of the active layer 104.

More specifically, the peripheral portion of the resonator R is increased in resistance by ion implantation in the entire region in the thickness direction of each of the tunnel junction layer 106, the first cladding layer 105, and the active layer 104.

The impurity concentration in the ion implantation is preferably less than 1×10¹⁹ cm⁻³.

The impurity in the ion implantation preferably includes at least one of H, B, C, or O.

### (2) Operation of Surface Emitting Laser

In the surface emitting laser 100, for example, the current supplied from the laser driver and flowing from the anode electrode 109 into the third cladding layer 107 is injected into the active layer 104 while being narrowed in the current confinement region CCR, and the active layer 104 emits light. The current that has passed through the active layer 104 passes through the second cladding layer 103 and flows out from the cathode electrode 110 to, for example, the laser driver. The light generated in the active layer 104 reciprocates between the first and second reflectors 108 and 102, is amplified in the active layer 104 during the reciprocation, and is emitted as laser light from the upper surface (emission surface) of the first reflector 108 when an oscillation condition is satisfied.

### (3) First Example of Method for Manufacturing Surface Emitting Laser

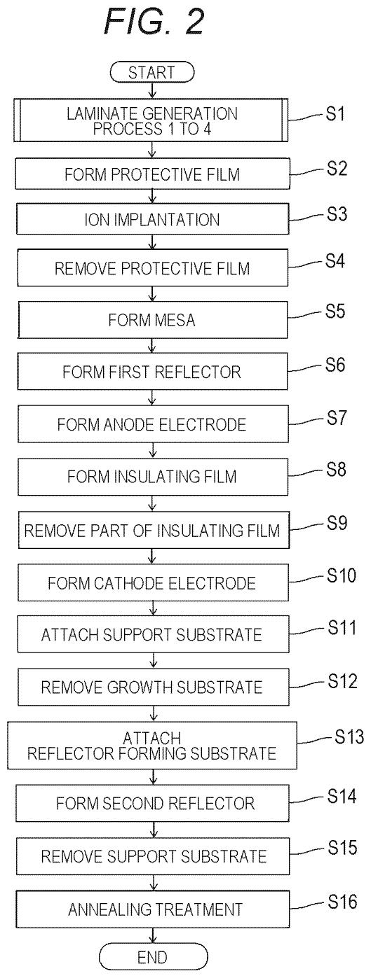

Hereinafter, a first example of the method for manufacturing the surface emitting laser 100 will be described with reference to the flowchart (steps S1 to S16) of FIG. 2. Here, as an example, a plurality of surface emitting laser arrays in which a plurality of surface emitting lasers 100 is two-dimensionally arranged on one wafer serving as a base material of the substrate 130 is simultaneously generated by a semiconductor manufacturing method using a semiconductor manufacturing apparatus. Next, a series of a plurality of integrated surface emitting laser arrays is separated from each other to obtain a plurality of chip-shaped surface emitting laser arrays (surface emitting laser array chips). Note that, by the manufacturing method described below, it is also possible to simultaneously generate a plurality of surface emitting lasers 100 on one wafer to be a base material of the substrate 130 and separate a series of the plurality of integrated surface emitting lasers 100 from each other to obtain a chip-shaped surface emitting laser (surface emitting laser chip).

As an example, the surface emitting laser 100 is manufactured by the CPU of the semiconductor manufacturing apparatus according to the procedure of the flowchart of FIG. 2.

### <Step S1>

In step S1, a laminate generation process (for example, a laminate generation process 1 described later) is performed. In the laminate generation process, as an example, each constituent layer of the surface emitting laser 100 is sequentially laminated (epitaxially grown) on a growth substrate 101 (for example, InP substrate) in a growth chamber by a metal organic chemical vapor deposition method (MOCVD method) or a molecular beam epitaxy method (MBE method) to generate a laminate (for example, a laminate L1). That is, in the laminate generation process, a laminate is generated by single epitaxial growth.

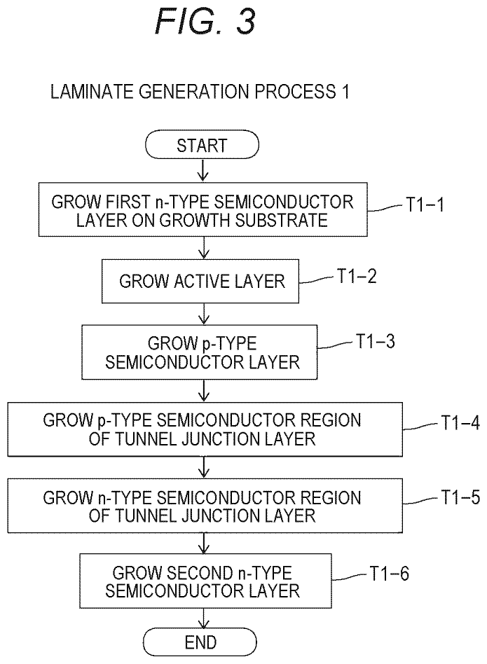

Hereinafter, the laminate generation process 1 as an example of the laminate generation process will be described with reference to the flowchart (steps T1-1 to T1-6) of FIG. 3.

In the first step T1-1, as an example, the second cladding layer 103 (for example, an n-InP layer) is grown as a first n-type semiconductor layer on the growth substrate 101 (for example, an InP substrate).

In the next step T1-2, the active layer 104 is grown on the second cladding layer 103.

In the next step T1-3, the first cladding layer 105 (for example, a p-InP layer) is grown as a p-type semiconductor layer on the active layer 104.

In the next step T1-4, the p-type semiconductor region 106a of the tunnel junction layer 106 is grown on the first cladding layer 105.

In the next step T1-5, the n-type semiconductor region 106b of the tunnel junction layer 106 is grown on the p-type semiconductor region 106a.

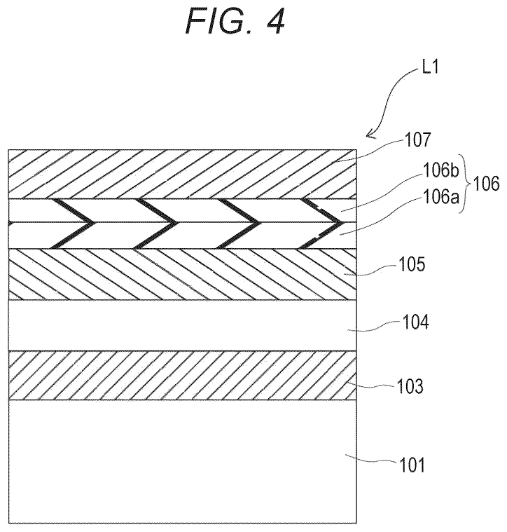

In the final step T1-6, the third cladding layer 107 (for example, an n-InP layer) is grown as a second n-type semiconductor layer on the n-type semiconductor region 106b. As a result, the laminate L1 (see FIG. 4) is generated.

### <Step S2>

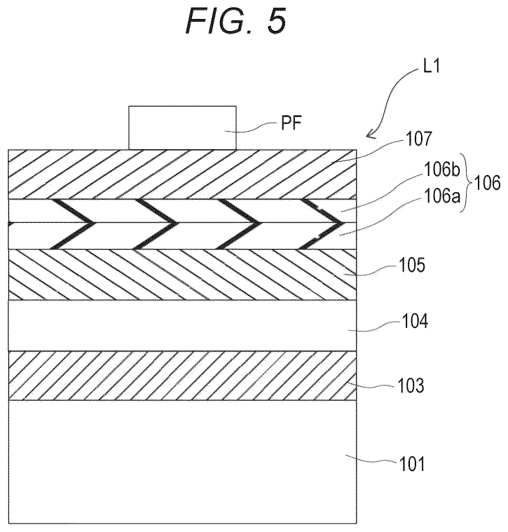

In step S2, a protective film PF is formed on the laminate L1 (see FIG. 5). Specifically, a region where ion implantation of the laminate L1 is not performed, which will be described later, is protected by a protective film PF constituted by a resist, SiO₂, or the like.

### <Step S3>

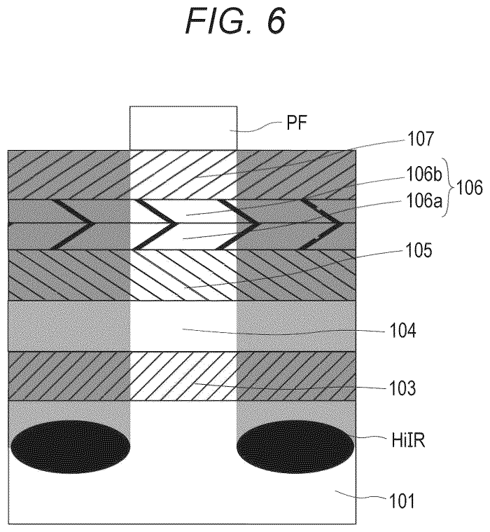

In step S3, ion implantation is performed (see FIG. 6). Specifically, ions are implanted into a peripheral portion of the laminate L1 (a circling region (for example, an annular region) where the current confinement region CCR is formed) from the third cladding layer 107 side (a portion painted in gray in FIG. 6). At this time, for example, protons (H⁺) are used as ion species, ion implantation energy is set so that protons reach (preferably concentrate) in the growth substrate 101, and the dose amount is set to 1×10¹⁴ ion/cm² or more. As a result, crystal defects due to ion implantation occur, and the resistance of the region into which ions are implanted increases. That is, a peripheral portion of the third cladding layer 107, a peripheral portion of the tunnel junction layer 106, a peripheral portion of the first cladding layer 105, a peripheral portion of the active layer 104, a peripheral portion of the second cladding layer 103, and a peripheral portion of the growth substrate 101 have high resistance. As a result, a high-concentration ion region HiIR (black coated portion in FIG. 6) including a region where the ion concentration is peak is formed in the growth substrate 101.

### <Step S4>

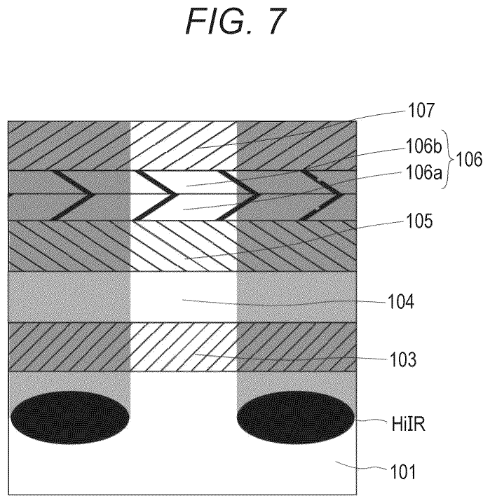

In step S4, the protective film PF is removed (see FIG. 7).

### <Step S5>

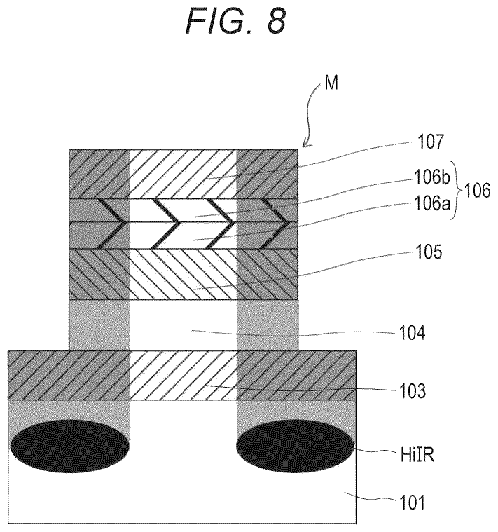

In step S5, the mesa M is formed (see FIG. 8). Specifically, as an example, the mesa M is formed by etching the third cladding layer 107, the tunnel junction layer 106, the first cladding layer 105, and the active layer 104. More specifically, a resist pattern for forming the mesa M on the third cladding layer 107 of the ion-implanted laminate L1 (see FIG. 7) is generated by photolithography. Next, using this resist pattern as a mask, etching is performed at least until the surface of the second cladding layer 103 is exposed (at least until the side surface of the active layer 104 is completely exposed) by wet etching or dry etching, for example, to form a mesa M having a diameter of 5 to 100 μm, for example. Thereafter, the resist pattern is removed.

### <Step S6>

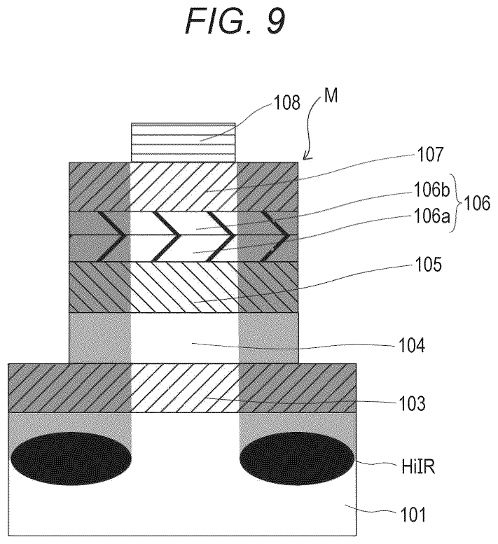

In step S6, the first reflector 108 is formed (see FIG. 9). Specifically, the dielectric multilayer film reflector as the first reflector 108 is formed on the central portion of the top portion of the mesa M.

### <Step S7>

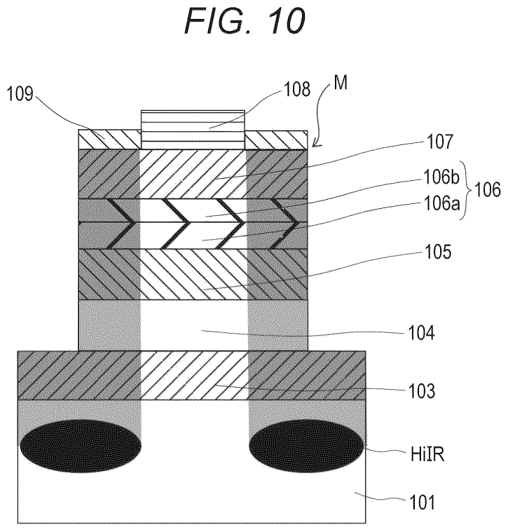

In step S7, the anode electrode 109 is formed (see FIG. 10). Specifically, for example, the anode electrode 109 having a circular shape (for example, an annular shape) is formed on the peripheral portion of the top portion of the mesa M by a lift-off method so as to surround the first reflector 108.

### <Step S8>

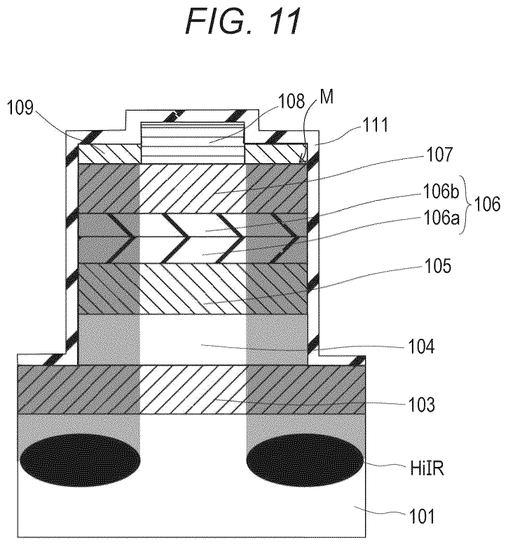

In step S8, the insulating film 111 is formed (see FIG. 11). Specifically, the insulating film 111 constituted by, for example, SiO₂ or the like is formed so as to cover the first reflector 108, the anode electrode 109, the side surface of the mesa M, and the peripheral region of the mesa M.

### <Step S9>

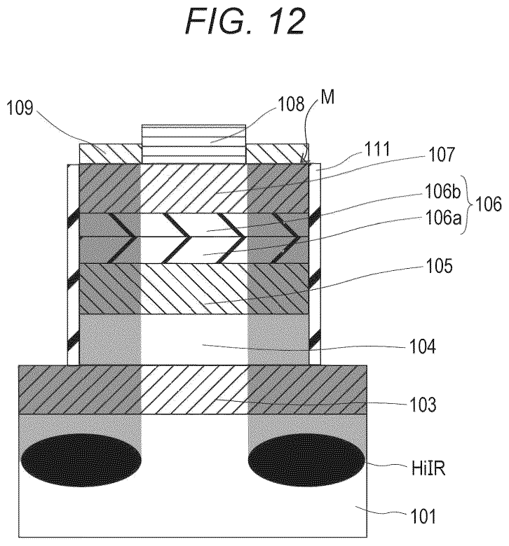

In step S9, a part of the insulating film 111 is removed (see FIG. 12). Specifically, the insulating film 111 on the first reflector 108 and the anode electrode 109 and the insulating film 111 on the peripheral region of the mesa M are removed by etching. As a result, only the insulating film 111 formed on the side surface of the mesa M remains.

### <Step S10>

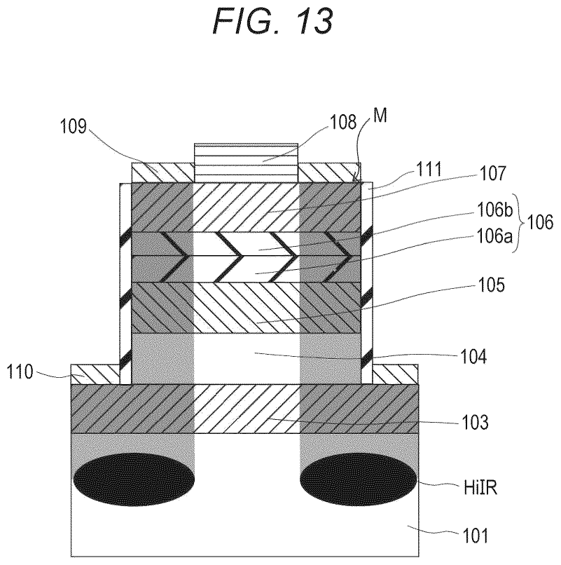

In step S10, the cathode electrode 110 is formed (see FIG. 13). Specifically, for example, the cathode electrode 110 having a circular shape (for example, an annular shape) is formed so as to take in the bottom portion of the mesa M via the insulating film 111 by a lift-off method.

### <Step S11>

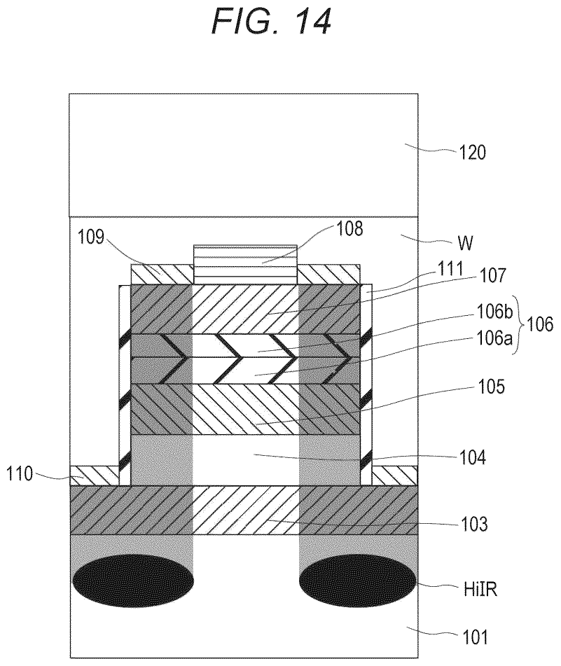

In step S11, a support substrate 120 is attached (see FIG. 14). Specifically, the support substrate 120 is attached to the embedding layer formed by embedding the periphery of the mesa M with the wax W.

### <Step S12>

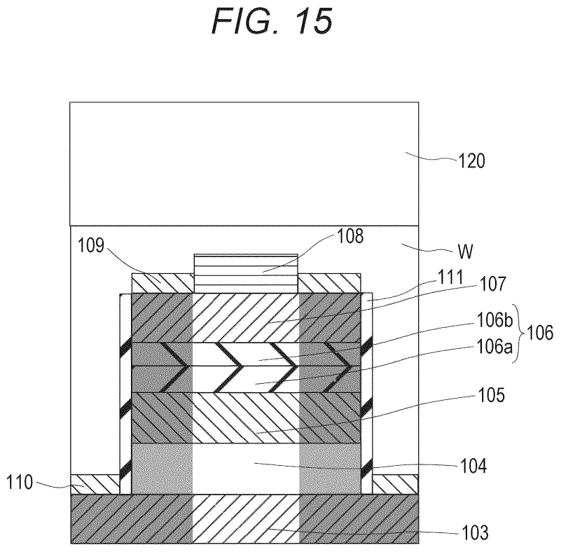

In step S12, the growth substrate 101 is removed (see FIG. 15). Specifically, first, the back surface of the growth substrate 101 is polished and thinned using a back grinder. Next, for example, the growth substrate 101 is removed by wet etching using a mixed solution of hydrochloric acid and phosphoric acid. As a result, the second cladding layer 103 is exposed. Here, in the laminate generation process 1, by stacking an InGaAsP layer as an etching stop layer between the growth substrate 101 and the second cladding layer 103, the wet etching can be stopped. The InGaAsP layer can be removed using a mixed solution of sulfuric acid, hydrogen peroxide, and water.

### <Step S13>

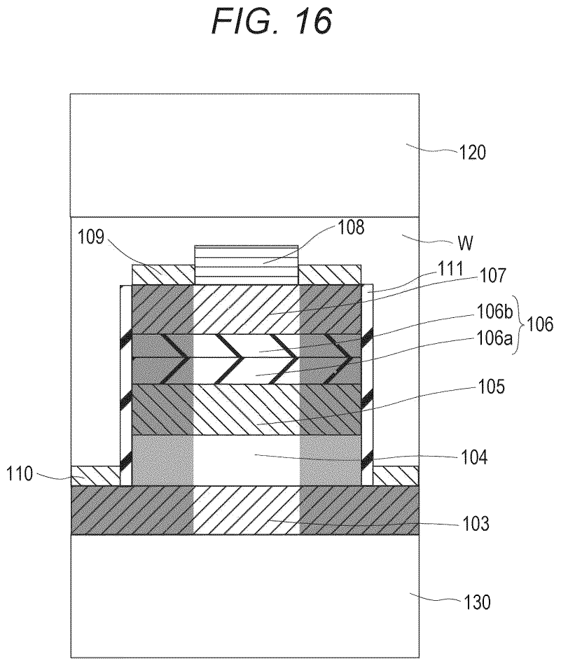

In step S13, the reflector forming substrate 130 is attached (see FIG. 16). Specifically, the second cladding layer 103 and the reflector forming substrate 130 are bonded. At this time, for example, a bonding surface of the second cladding layer 103 with the reflector forming substrate 130 and a bonding surface of the reflector forming substrate 130 with the second cladding layer 103 are subjected to plasma treatment to clean each bonding surface, and then both the bonding surfaces are bonded to each other, thereby bonding the second cladding layer 103 and the reflector forming substrate 130.

### <Step S14>

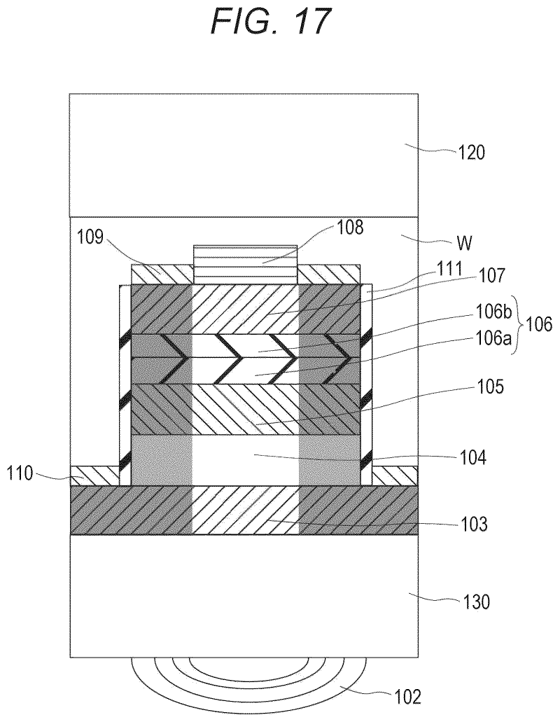

In step S14, the second reflector 102 is formed on the reflector forming substrate 130 (see FIG. 17). Specifically, first, a resist is applied to the central portion of the back surface (lower surface) of the reflector forming substrate 130, and the reflector forming substrate 130 is dry-etched using a mask obtained by heating the resist and hemispherizing the resist. Next, a dielectric multilayer film reflector as the second reflector 102 is formed by forming a dielectric layer in multiple layers on the remaining hemispherical portion of the reflector forming substrate 130 by etching.

### <Step S15>

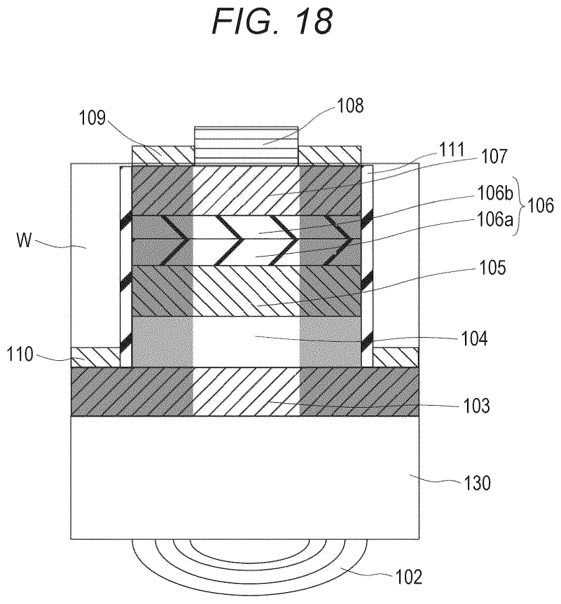

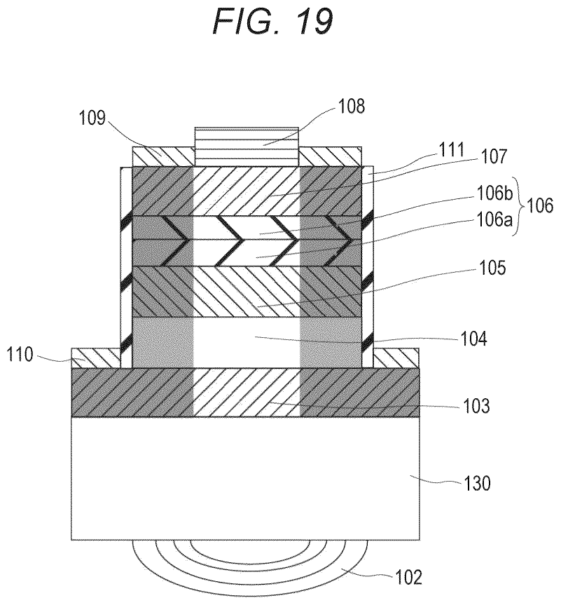

In step S15, the support substrate 120 is removed (see FIGS. 18 and 19). Specifically, the support substrate 120 is removed by heating at 200 to 300° C. to soften the wax W constituting the embedding layer. After the support substrate 120 is removed, the remaining wax W (FIG. 18) is removed by an asher (see FIG. 19). Along with the removal of the support substrate 120, the high-concentration ion region HiIR is also removed.

### <Step S16>

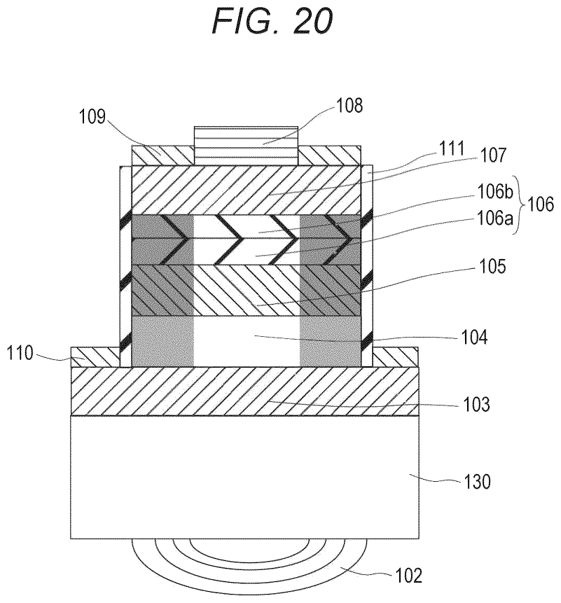

In step S16, an annealing treatment is performed (see FIG. 20). Specifically, the annealing treatment is performed at 350 to 500° C. As a result, the peripheral portions of the second and third cladding layers 103 and 107, which are n-InP layers damaged (having crystal defects) by ion implantation, are recovered with reduced resistance. On the other hand, the peripheral portion of the tunnel junction layer 106, the peripheral portion of the first cladding layer 105, and the peripheral portion of the active layer 104 damaged by ion implantation remain high in resistance and are not recovered. Note that it is reported in the article (J. Appl. Phys. Vol. 89, No. 10, 15 (2001)) that n-InP with increased resistance is recovered by the annealing treatment, and p-InP with increased resistance is not recovered by the annealing treatment. Furthermore, in this paper, it is reported that n-GaAs having high resistance is recovered by annealing treatment, and p-GaAs having high resistance is not recovered by annealing treatment.

The annealing treatment here can also serve as a sinter for each electrode. When step S16 is executed, the flow of FIG. 2 ends.

### (4) Second Example of Method for Manufacturing Surface Emitting Laser

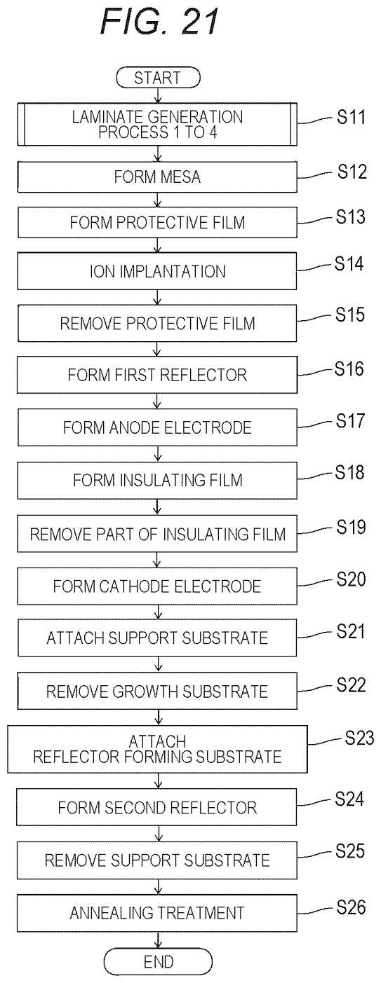

Hereinafter, a second example of the method for manufacturing the surface emitting laser 100 will be described with reference to the flowchart (steps S11 to S26) of FIG. 21. Here, as an example, a plurality of surface emitting laser arrays in which a plurality of surface emitting lasers 100 is two-dimensionally arranged on one wafer serving as a base material of the substrate 130 is simultaneously generated by a semiconductor manufacturing method using a semiconductor manufacturing apparatus. Next, a series of a plurality of integrated surface emitting laser arrays is separated from each other to obtain a plurality of chip-shaped surface emitting laser arrays (surface emitting laser array chips). Note that, by the manufacturing method described below, it is also possible to simultaneously generate a plurality of surface emitting lasers 100 on one wafer to be a base material of the substrate 130 and separate a series of the plurality of integrated surface emitting lasers 100 from each other to obtain a chip-shaped surface emitting laser (surface emitting laser chip).

As an example, the surface emitting laser 100 is manufactured by the CPU of the semiconductor manufacturing apparatus according to the procedure of the flowchart of FIG. 21.

### <Step S11>

In step S11, a laminate generation process (for example, the laminate generation process 1 described above) is performed. In the laminate generation process, as an example, each constituent layer of the surface emitting laser 100 is sequentially laminated (epitaxially grown) on a growth substrate 101 (for example, InP substrate) in a growth chamber by a metal organic chemical vapor deposition method (MOCVD method) or a molecular beam epitaxy method (MBE method) to generate a laminate (for example, a laminate L1). That is, in the laminate generation process, a laminate is generated by single epitaxial growth.

### <Step S12>

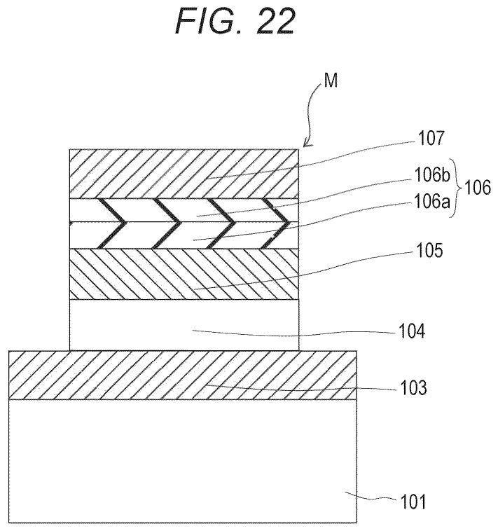

In step S12, the mesa M is formed (see FIG. 22). Specifically, as an example, the mesa M is formed by etching the third cladding layer 107, the tunnel junction layer 106, the first cladding layer 105, and the active layer 104. More specifically, a resist pattern for forming the mesa M on the third cladding layer 107 of the laminate L1 (see FIG. 4) is generated by photolithography. Next, using this resist pattern as a mask, etching is performed at least until the surface of the second cladding layer 103 is exposed (at least until the side surface of the active layer 104 is completely exposed) by wet etching or dry etching, for example, to form a mesa M having a diameter of 5 to 100 μm, for example. Thereafter, the resist pattern is removed.

### <Step S13>

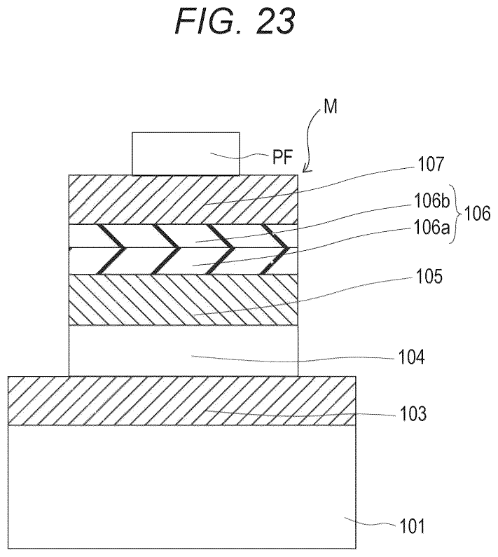

In step S13, the protective film PF is formed on the mesa M (see FIG. 23). Specifically, a region where ion implantation of the mesa M is not performed, which will be described later, is protected by a protective film PF constituted by a resist, SiO₂, or the like.

### <Step S14>

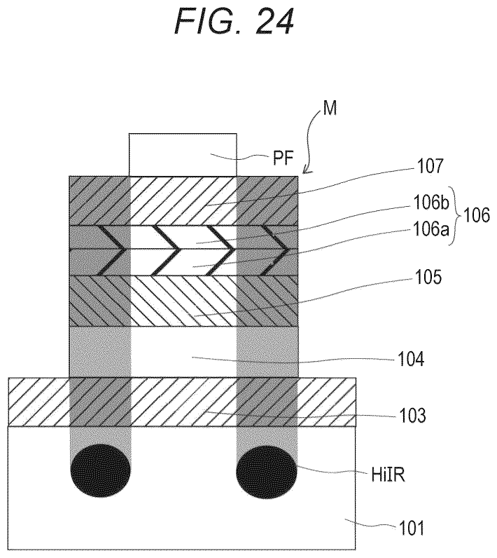

In step S14, ion implantation is performed (see FIG. 24). Specifically, ions are implanted into a peripheral portion of the mesa M (a circling region (for example, an annular region) in which the current confinement region CCR is formed). At this time, for example, protons (H1 are used as ion species, ion implantation energy is set so that protons reach (preferably concentrate) in the growth substrate 101, and the dose amount is set to 1×10¹⁴ ion/cm² or more. As a result, crystal defects due to ion implantation occur, and the resistance of the region into which ions are implanted increases. That is, a peripheral portion of the third cladding layer 107, a peripheral portion of the tunnel junction layer 106, a peripheral portion of the first cladding layer 105, a peripheral portion of the active layer 104, a peripheral portion of the second cladding layer 103, and a peripheral portion of the growth substrate 101 have high resistance. As a result, a high-concentration ion region HiIR (black coated portion in FIG. 24) including a region where the ion concentration is peak is formed in the growth substrate 101.

### <Step S15>

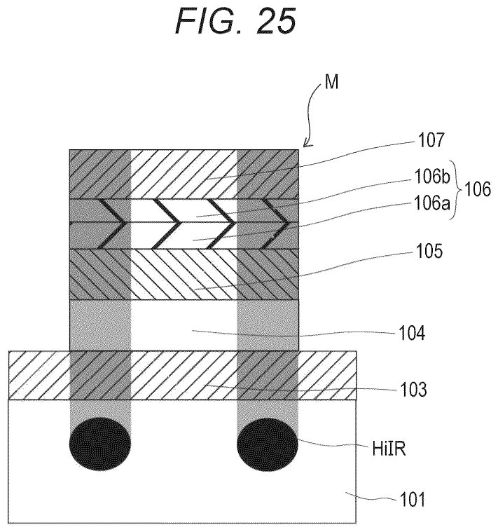

In step S15, the protective film PF is removed (see FIG. 25).

### <Step S16>

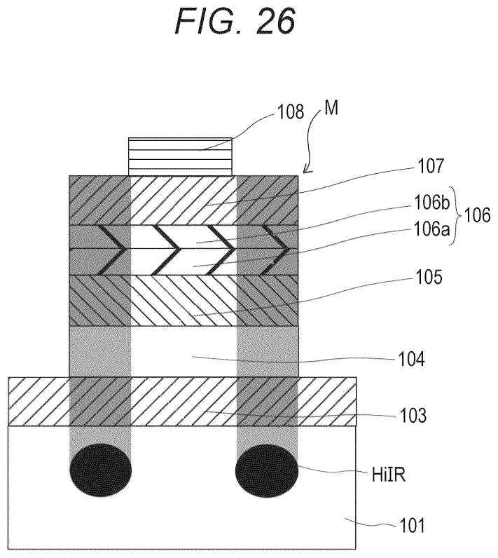

In step S16, the first reflector 108 is formed (see FIG. 26). Specifically, the dielectric multilayer film reflector as the first reflector 108 is formed on the central portion of the top portion of the mesa M.

### <Step S17>

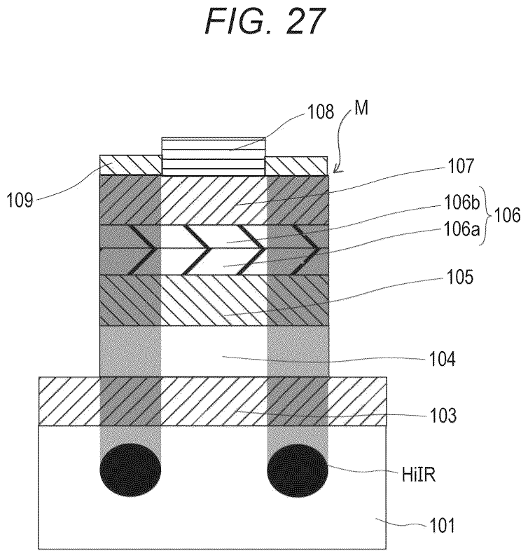

In step S17, the anode electrode 109 is formed (see FIG. 27). Specifically, for example, the anode electrode 109 having a circular shape (for example, an annular shape) is formed on the peripheral portion of the top portion of the mesa M by a lift-off method so as to surround the first reflector 108.

### <Step S18>

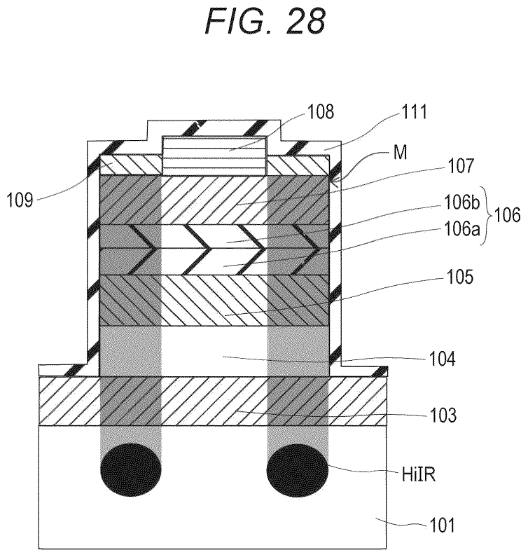

In step S18, the insulating film 111 is formed (see FIG. 28). Specifically, the insulating film 111 constituted by, for example, SiO₂ or the like is formed so as to cover the first reflector 108, the anode electrode 109, the side surface of the mesa M, and the peripheral region of the mesa M.

### <Step S19>

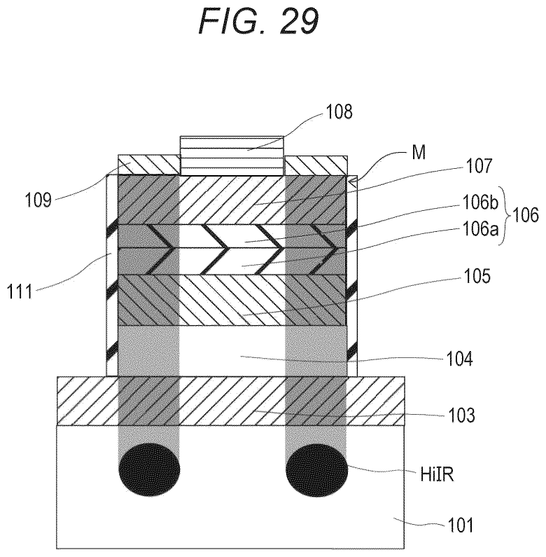

In step S19, a part of the insulating film 111 is removed (see FIG. 29). Specifically, the insulating film 111 on the first reflector 108 and the anode electrode 109 and the insulating film 111 on the peripheral region of the mesa M are removed by etching. As a result, only the insulating film 111 formed on the side surface of the mesa M remains.

### <Step S20>

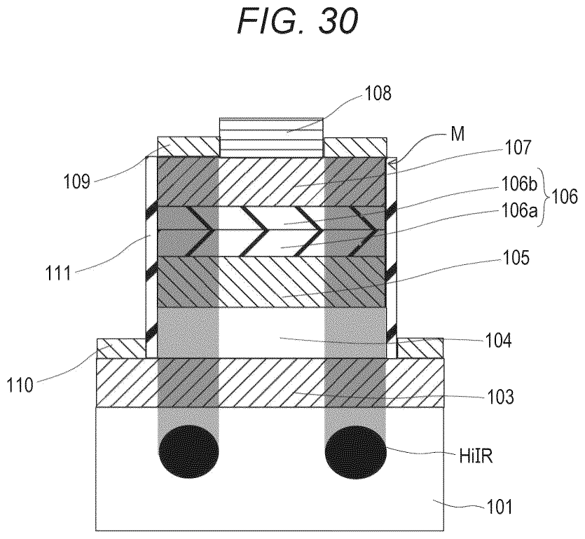

In step S20, the cathode electrode 110 is formed (see FIG. 30). Specifically, for example, the cathode electrode 110 having a circular shape (for example, an annular shape) is formed so as to take in the bottom portion of the mesa M via the insulating film 111 by a lift-off method.

### <Step S21>

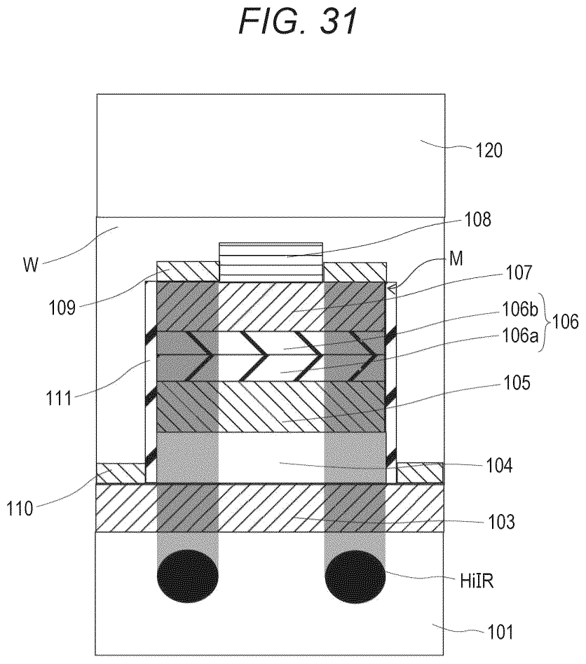

In step S21, the support substrate 120 is attached (see FIG. 31). Specifically, the support substrate 120 is attached to the embedding layer formed by embedding the periphery of the mesa M with the wax W.

### <Step S22>

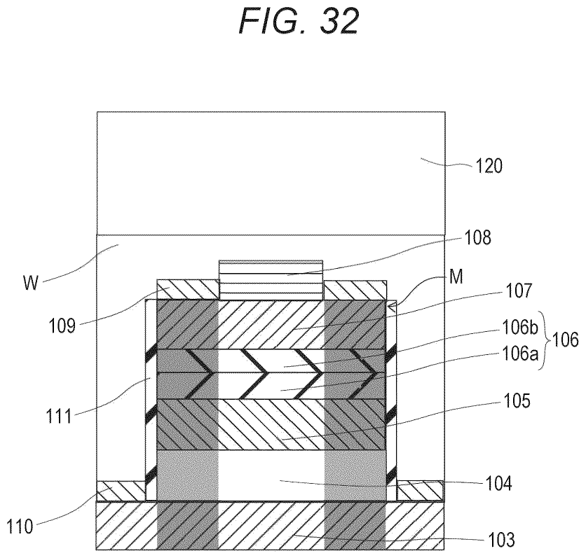

In step S22, the growth substrate 101 is removed (see FIG. 32). Specifically, first, the back surface of the growth substrate 101 is polished and thinned using a back grinder. Next, for example, the growth substrate 101 is removed by wet etching using a mixed solution of hydrochloric acid and phosphoric acid. As a result, the second cladding layer 103 is exposed. Also here, in the laminate generation process 1, by stacking an InGaAsP layer as an etching stop layer between the growth substrate 101 and the second cladding layer 103, the wet etching can be stopped. The InGaAsP layer can be removed using a mixed solution of sulfuric acid, hydrogen peroxide, and water.

### <Step S23>

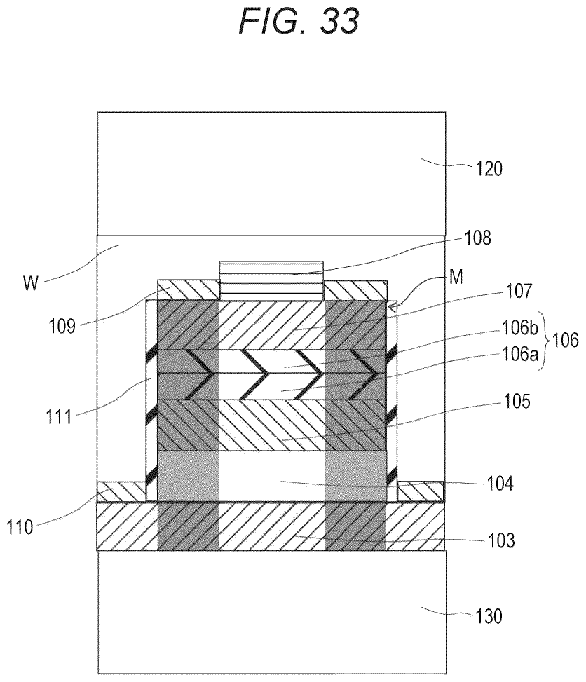

In step S23, the reflector forming substrate 130 is attached (see FIG. 33). Specifically, the second cladding layer 103 and the reflector forming substrate 130 are bonded. At this time, for example, a bonding surface of the second cladding layer 103 with the reflector forming substrate 130 and a bonding surface of the reflector forming substrate 130 with the second cladding layer 103 are subjected to plasma treatment to clean each bonding surface, and then both the bonding surfaces are bonded to each other, thereby bonding the second cladding layer 103 and the reflector forming substrate 130.

### <Step S24>

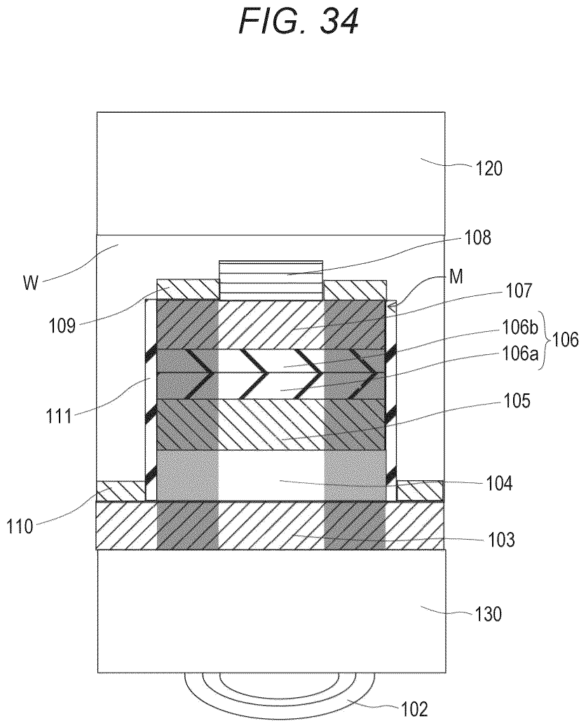

In step S24, the second reflector 102 is formed on the reflector forming substrate 130 (see FIG. 34). Specifically, first, a resist is applied to the central portion of the back surface (lower surface) of the reflector forming substrate 130, and the reflector forming substrate 130 is dry-etched using a mask obtained by heating the resist and hemispherizing the resist. Next, a dielectric multilayer film reflector as the second reflector 102 is formed by forming a dielectric layer in multiple layers on the remaining hemispherical portion of the reflector forming substrate 130 by etching.

### <Step S25>

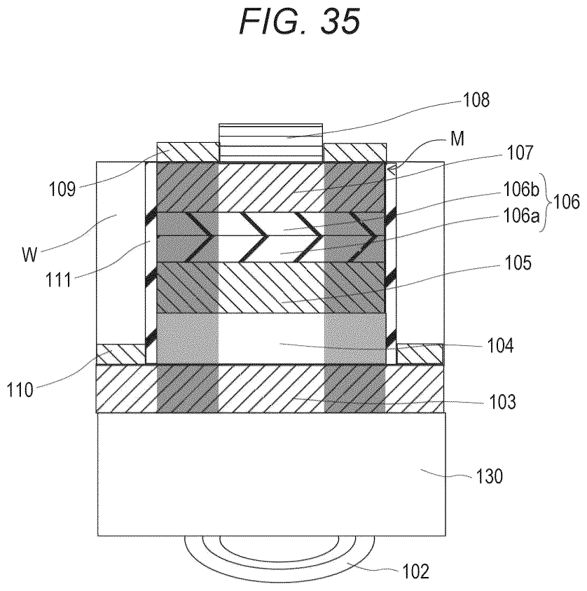

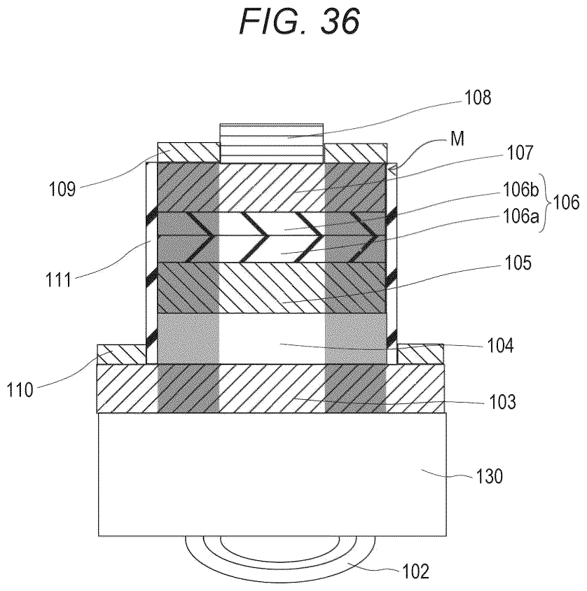

In step S25, the support substrate 120 is removed (see FIGS. 35 and 36). Specifically, the support substrate 120 is removed by heating at 200 to 300° C. to soften the wax W constituting the embedding layer. After the support substrate 120 is removed, the remaining wax W (FIG. 35) is removed by an asher (see FIG. 36). Along with the removal of the support substrate 120, the high-concentration ion region HiIR is also removed.

### <Step S26>

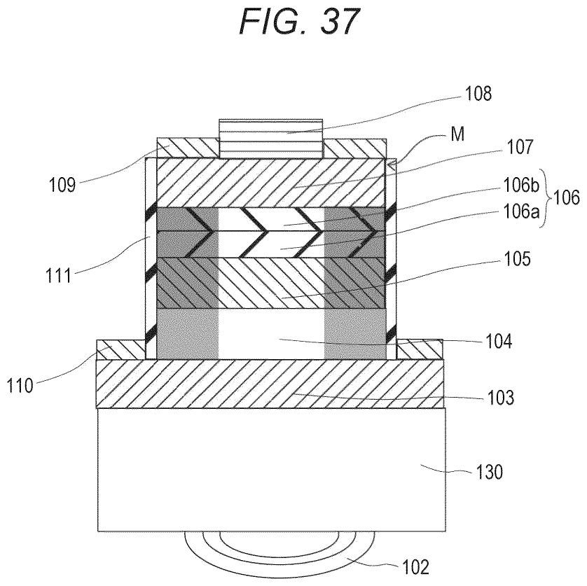

In step S26, an annealing treatment is performed (see FIG. 37). Specifically, the annealing treatment is performed at 350 to 500° C. As a result, the second and third cladding layers 103 and 107, which are n-InP layers damaged (in which crystal defects have occurred) by ion implantation, are recovered with reduced resistance. On the other hand, the tunnel junction layer 106, the first cladding layer 105, and the active layer 104 damaged by ion implantation remain high in resistance and are not recovered. The annealing treatment here can also serve as a sinter for each electrode. When step S26 is executed, the flow of FIG. 21 ends.

### (5) Effects of Surface Emitting Laser and Method for Manufacturing the Same

The surface emitting laser 100 according to the first embodiment of the present technology includes the first and second reflectors 108 and 102, and the resonator R including the active layer 104 and the tunnel junction layer 106 disposed between the first and second reflectors 108 and 102, and the peripheral portion of the resonator R has higher resistance than the central portion at least in the entire region in the thickness direction of the tunnel junction layer 106.

In this case, for example, in order to inject ions into the entire region in the thickness direction of the peripheral portion of the tunnel junction layer 106 when the peripheral portion of the tunnel junction layer 106 is increased in resistance by ion implantation, it is necessary to cause the ions to reach at least the boundary between the layer (for example, the first cladding layer 105) adjacent to the tunnel junction layer 106 and the tunnel junction layer 106, and a position where the ion concentration (for example, hydrogen ion concentration) becomes a peak does not exist at least in the tunnel junction layer 106.

As a result, according to the surface emitting laser 100, it is possible to provide a surface emitting laser capable of current confinement at least in the tunnel junction layer 106 while suppressing the characteristic change of the tunnel junction layer 106.

Furthermore, according to the surface emitting laser 100, it is possible to provide a surface emitting laser capable of narrowing a current at least in the tunnel junction layer 106 without performing epitaxial growth a plurality of times. As a result, it is possible to shorten the manufacturing time and reduce the manufacturing cost.

For example, according to the surface emitting laser 100, in order to generate the current confinement structure, it is not necessary to etch the tunnel junction layer to form the BTJ, and it is not necessary to perform etching and subsequent embedded regrowth, so that the number of manufacturing steps can be reduced.

According to the surface emitting laser 100, flatness on the tunnel junction layer 106 can be enhanced as compared with the case of forming the BTJ, so that it is possible to attach a semiconductor multilayer film reflector constituted by a compound semiconductor (for example, a GaAs compound semiconductor, an AlGaAs-based compound semiconductor, or the like) having high heat dissipation, for example, on the tunnel junction layer 106.

The resonator R includes the first cladding layer 105 between the tunnel junction layer 106 and the active layer 104, and in the first cladding layer 105, at least a peripheral portion of a portion on the tunnel junction layer 106 side has higher resistance than a central portion. As a result, the current can be narrowed also in the first cladding layer 105.

The first cladding layer 105 can be, for example, a p-type semiconductor layer.

The first cladding layer 105 is preferably constituted by, for example, a p-type InP compound semiconductor (for example, p-InP). In this case, this is particularly effective in a case where the surface emitting laser 100 is a long-wavelength surface emitting laser having an oscillation wavelength of 1.3 μm or more.

In the active layer 104, at least a peripheral portion of a portion on the tunnel junction layer 106 side has higher resistance than a central portion. As a result, the current can be narrowed also in the active layer 104.

The resonator R includes the second cladding layer 103 on the side opposite to the tunnel junction layer 106 side of the active layer 104, and the second cladding layer 103 has lower resistance in the central portion and the peripheral portion than in the peripheral portion of the tunnel junction layer 106. As a result, a current path can be formed in a direction including the in-plane direction of the second cladding layer 103.

The cathode electrode 110 is provided on the second cladding layer 103. As a result, the current narrowed in the current confinement region CCR and flowing in the direction including the in-plane direction of the second cladding layer 103 can flow out from the cathode electrode 110 to the outside (for example, a laser driver).

The second cladding layer 103 can be, for example, an n-type semiconductor layer.

The second cladding layer 103 is preferably constituted by, for example, an n-type InP compound semiconductor (for example, n-InP). In this case, this is particularly effective in a case where the surface emitting laser 100 is a long-wavelength surface emitting laser having an oscillation wavelength of 1.3 μm or more.

The resonator R includes the third cladding layer 107 on the side opposite to the active layer 104 side of the tunnel junction layer 106, and the third cladding layer 107 has lower resistance in the central portion and the peripheral portion than in the peripheral portion of the tunnel junction layer 106. As a result, for example, the third cladding layer 107 can function as a contact layer in contact with the electrode.

The anode electrode 109 is provided on the third cladding layer 107. As a result, the current flowing through the anode electrode 109 can efficiently flow into the third cladding layer 107.

The third cladding layer 107 can be, for example, an n-type semiconductor layer.

The third cladding layer 107 is preferably constituted by an n-type InP compound semiconductor (for example, n-InP). In this case, this is particularly effective in a case where the surface emitting laser 100 is a long-wavelength surface emitting laser having an oscillation wavelength of 1.3 μm or more.

In the resonator R, the peripheral portion is increased in resistance by ion implantation at least in the entire region in the thickness direction of the tunnel junction layer 106. As a result, it is possible to narrow the current at least in the tunnel junction layer 106 without forming the BTJ and while suppressing the characteristic change of the tunnel junction layer 106.

The impurity concentration (for example, hydrogen ion concentration) in the ion implantation is preferably less than 1×10¹⁹ cm⁻³. As a result, it is possible to suppress the characteristic change in each layer constituting the resonator R.

The impurity in the ion implantation preferably includes at least one of H, B, C, or O.

The substrate 130 disposed between the resonator R and the second reflector 102 that is a reflector closer to the active layer 104 than the tunnel junction layer 106 among the first and second reflectors 108 and 102 is further included, and the second reflector 102 is a concave multilayer film reflector. As a result, the second reflector 102 has both a function as a high reflectance reflector and a light confinement function.

The thermal conductivity of the substrate 130 is preferably, for example, 40 W/m·K or more. As a result, the heat dissipation of the heat generated in the resonator R can be improved.

The substrate 130 is preferably constituted by, for example, any of GaAs, Si, and SiC.

According to the surface emitting laser array including the plurality of surface emitting lasers 100, it is possible to provide the surface emitting laser array including the plurality of surface emitting lasers capable of performing current confinement at least in the tunnel junction layer 106 while suppressing the characteristic change of the tunnel junction layer 106 of each surface emitting laser 100.

The method for manufacturing the surface emitting laser 100 according to the first embodiment of the present technology includes a step of stacking the resonator R including the active layer 104 and the tunnel junction layer 106 on the growth substrate 101 (first substrate) to generate the laminate L1, and a step of implanting ions into the peripheral portion of the resonator R to make the peripheral portion higher in resistance than the central portion at least in the entire region in the thickness direction of the tunnel junction layer 106.

According to the method for manufacturing the surface emitting laser 100, it is possible to manufacture a surface emitting laser capable of performing current confinement at least in the tunnel junction layer 106 while suppressing the characteristic change of the tunnel junction layer 106.

The resonator R includes the first cladding layer 105 between the tunnel junction layer 106 and the active layer 104, and in the above step of increasing the resistance, ions are caused to reach at least a peripheral portion of a portion of the first cladding layer 105 on the tunnel junction layer 106 side, and the resistance of the peripheral portion is also increased. As a result, the surface emitting laser 100 capable of performing current confinement also in the first cladding layer 105 can be manufactured.

In the above step of increasing the resistance, ions are caused to reach at least the peripheral portion of the portion of the active layer 104 on the tunnel junction layer 106 side, and the resistance of the peripheral portion is also increased. As a result, the surface emitting laser 100 capable of performing current confinement even in the active layer 104 can be manufactured.

The resonator R includes the second cladding layer 103 on the side opposite to the tunnel junction layer 106 side of the active layer 104, and in the above step of increasing the resistance, ions are caused to reach at least a peripheral portion of a portion of the second cladding layer on the tunnel junction layer 106 side, and the resistance of the peripheral portion is also increased.

In the above step of increasing the resistance, ions are caused to reach the inside of the growth substrate 101. As a result, since the peak position of the ion concentration can be located in the growth substrate 101, the ion concentration in the resonator R can be relatively reduced, and the surface emitting laser 100 capable of suppressing the characteristic change of the resonator R can be manufactured.

The method for manufacturing the surface emitting laser 100 includes, after the above step of increasing the resistance, a step of bonding the support substrate 120 to the surface of the laminate on the resonator R side, and a step of removing the growth substrate 101 from the laminate. As a result, a portion having a peak of the ion concentration, which is highly likely to induce the characteristic change (for example, a decrease in reliability) of the element, can be excluded from the components of the surface emitting laser 100, so that it is possible to manufacture the surface emitting laser 100 capable of suppressing the characteristic change of each constituent layer.

The method for manufacturing the surface emitting laser 100 further includes a step of bonding the reflector forming substrate 130 (second substrate) to the surface of the laminate from which the growth substrate L1 has been removed, and a step of forming the second reflector 102 on the reflector forming substrate 130. As a result, for example, the surface emitting laser 100 that can form the second reflector 102 into a desired shape (for example, a concave shape) can be manufactured by processing the reflector forming substrate 130 as a base by etching or the like between the bonding step and the forming step.

The resonator R includes the third cladding layer 107 that is an n-type semiconductor layer on the side opposite to the active layer 104 side of the tunnel junction layer 106, in the step of increasing the resistance, the resistance of the peripheral portion of at least the portion of the third cladding layer 107 on the tunnel junction layer 106 side is also increased, and the method for manufacturing the surface emitting laser 100 further includes a step of reducing the resistance of the peripheral portion of at least the portion of the third cladding layer 107 on the tunnel junction layer 106 side by performing an annealing treatment on the laminate after the above step of increasing the resistance. As a result, the surface emitting laser 100 capable of causing the third cladding layer to function as a contact layer in contact with the electrode can be manufactured.

The resonator R includes the first cladding layer 105 that is a p-type semiconductor layer between the tunnel junction layer 106 and the active layer 104, and in the above step of increasing the resistance, the resistance of the peripheral portion of at least the portion of the first cladding layer 105 on the tunnel junction layer 106 side is also increased. As a result, the surface emitting laser 100 capable of narrowing the current even in the peripheral portion of the first cladding layer 105 can be manufactured.

In the above step of increasing the resistance, at least a portion of the active layer 104 on the tunnel junction layer 106 side also increases the resistance. As a result, the surface emitting laser 100 capable of narrowing the current even in the peripheral portion of the active layer 104 can be manufactured.

The resonator R includes the second cladding layer 103 that is an n-type semiconductor layer on the side opposite to the tunnel junction layer 106 side of the active layer 104, in the above step of increasing the resistance, the resistance of the peripheral portion of at least the portion of the second cladding layer 103 on the active layer 104 side is also increased, and the method for manufacturing the surface emitting laser 100 further includes a step of reducing the resistance of the peripheral portion of at least the portion of the second cladding layer 103 on the active layer 104 side by performing an annealing treatment on the laminate after the above step of increasing the resistance. As a result, it is possible to manufacture the surface emitting laser 100 in which the current path exists in the direction including the in-plane direction in the second cladding layer 103.

### 3. Surface Emitting Lasers According to Modifications 1 to 5 of First Embodiment of Present Technology

Hereinafter, surface emitting lasers according to Modifications 1 to 5 of the first embodiment of the present technology will be described.

### Modification 1

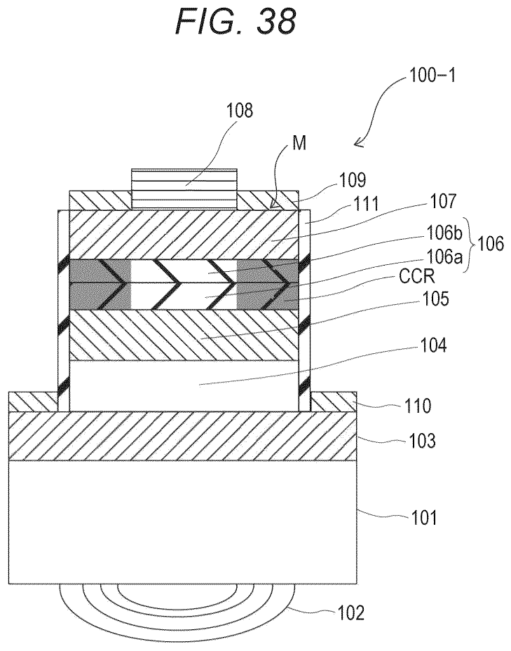

As illustrated in FIG. 38, a surface emitting laser 100-1 of Modification 1 has a similar configuration to the surface emitting laser 100 of the first embodiment except that the resistance is increased only in the entire region in the thickness direction of the peripheral portion of the tunnel junction layer 106. That is, in the surface emitting laser 100-1, the entire region in the thickness direction of the peripheral portion of the tunnel junction layer 106 constitutes the current confinement region CCR.

The surface emitting laser 100-1 can also be manufactured by the procedure of the flowchart of FIG. 2 or 21 substantially similarly to the surface emitting laser 100. Note that, in the method for manufacturing the surface emitting laser 100-1, since ions are not caused to reach the growth substrate 101, it is not necessary to remove the growth substrate 101. Therefore, for example, instead of steps S11 to S15 in FIG. 2 and steps S21 to S25 in FIG. 21, a step (process) of forming the second reflector 102 on the growth substrate 101 is only required to be performed.

At the time of manufacturing the surface emitting laser 100-1, when ion implantation is performed from the third cladding layer 107 side with respect to the peripheral portion of the laminate or the peripheral portion of the mesa formed by etching the laminate, the ion implantation energy is adjusted such that ions are implanted only in the entire region in the thickness direction of the peripheral portion of the third cladding layer 107 and the entire region in the thickness direction of the peripheral portion of the tunnel junction layer 106. As a result, the peak position of the ion concentration becomes the boundary between the tunnel junction layer 106 and the first cladding layer 105.

Therefore, only the peripheral portion of the third cladding layer 107 and the peripheral portion of the tunnel junction layer 106 are increased in resistance by ion implantation, and only the third cladding layer 107 is decreased in resistance by the subsequent annealing treatment and recovered.

According to the surface emitting laser 100-1, although the current confinement effect cannot be obtained in the first cladding layer 105 and the active layer 104, since the ion implantation depth can be made extremely shallow at the time of forming the current confinement region CCR, the width controllability of the current confinement region CCR is extremely excellent, and the manufacturing can be performed with a small number of steps, so that the productivity is high.

### Modification 2

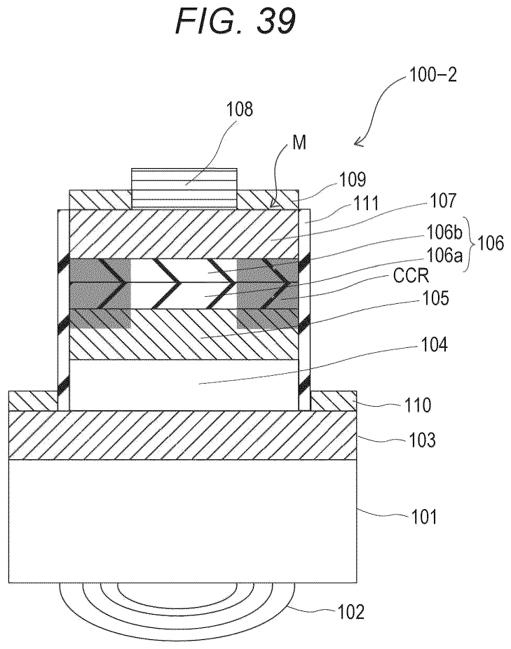

As illustrated in FIG. 39, a surface emitting laser 100-2 of Modification 2 has a similar configuration to the surface emitting laser 100 of the first embodiment except that the entire region in the thickness direction of the peripheral portion of the tunnel junction layer 106 and only the upper portion of the peripheral portion of the first cladding layer 105 (portion on the tunnel junction layer 106 side) are increased in resistance. That is, in the surface emitting laser 100-2, the entire region in the thickness direction of the peripheral portion of the tunnel junction layer 106 and the upper portion of the peripheral portion of the first cladding layer 105 constitute the current confinement region CCR.

The surface emitting laser 100-2 can also be manufactured by the procedure of the flowchart of FIG. 2 or 21 substantially similarly to the surface emitting laser 100. Note that, also in the method for manufacturing the surface emitting laser 100-2, since ions are not caused to reach the growth substrate 101, it is not necessary to remove the growth substrate 101. Therefore, for example, instead of steps S11 to S15 in FIG. 2 and steps S21 to S25 in FIG. 21, a step (process) of forming the second reflector 102 on the growth substrate 101 is only required to be performed.

At the time of manufacturing the surface emitting laser 100-2, when ion implantation is performed from the third cladding layer 107 side with respect to the peripheral portion of the laminate or the peripheral portion of the mesa formed by etching the laminate, ion implantation energy is adjusted such that ions are implanted into the entire region in the thickness direction of the peripheral portion of the third cladding layer 107, the entire region in the thickness direction of the peripheral portion of the tunnel junction layer 106, and only the upper portion of the peripheral portion of the first cladding layer 105. As a result, the peak position of the ion concentration is in the first cladding layer 105.

Therefore, only the peripheral portion of the third cladding layer 107, the peripheral portion of the tunnel junction layer 106, and the upper portion of the peripheral portion of the first cladding layer 105 are increased in resistance by ion implantation, and only the third cladding layer 107 is reduced in resistance by the subsequent annealing treatment and recovered.

According to the surface emitting laser 100-2, although the current confinement effect cannot be obtained in the lower portion of the first cladding layer 105 and the active layer 104, since the ion implantation depth can be made relatively shallow at the time of forming the current confinement region CCR, the width controllability of the current confinement region CCR is excellent, and since the peak position of the ion concentration can be moved away from the tunnel junction layer 106, the characteristic change of the tunnel junction layer 106 can be further suppressed, and manufacturing can be performed with a small number of steps, so that productivity is high.

### Modification 3

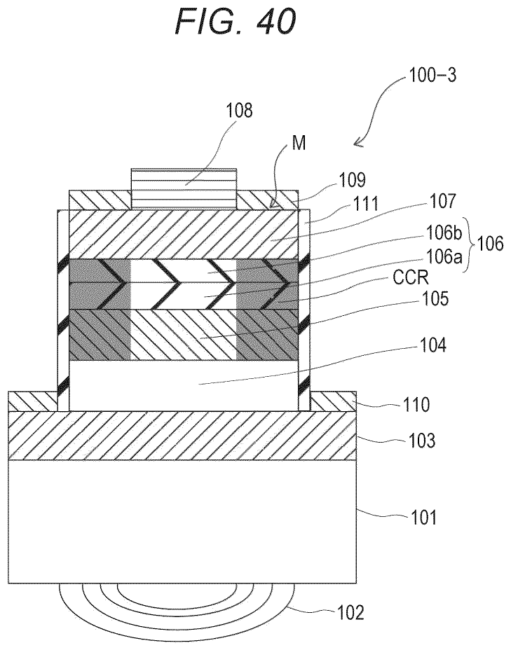

As illustrated in FIG. 40, a surface emitting laser 100-3 of Modification 3 has a similar configuration to the surface emitting laser 100 of the first embodiment except that the resistance is increased only in the entire region in the thickness direction of the peripheral portion of the tunnel junction layer 106 and in the entire region in the thickness direction of the peripheral portion of the first cladding layer 105. That is, in the surface emitting laser 100-2, the entire region in the thickness direction of the peripheral portion of the tunnel junction layer 106 and the entire region in the thickness direction of the peripheral portion of the first cladding layer 105 constitute the current confinement region CCR.

The surface emitting laser 100-3 is also manufactured by the procedure of the flowchart of FIG. 2 or 21 substantially similarly to the surface emitting laser 100. Note that, also in the method for manufacturing the surface emitting laser 100-3, since ions are not caused to reach the growth substrate 101, it is not necessary to remove the growth substrate 101. Therefore, for example, instead of steps S11 to S15 in FIG. 2 and steps S21 to S25 in FIG. 21, a step (process) of forming the second reflector 102 on the growth substrate 101 is only required to be performed.

At the time of manufacturing the surface emitting laser 100-3, when ion implantation is performed from the third cladding layer 107 side with respect to the peripheral portion of the laminate or the peripheral portion of the mesa formed by etching the laminate, the ion implantation energy is adjusted such that ions are implanted into the entire region in the thickness direction of the peripheral portion of the third cladding layer 107, the entire region in the thickness direction of the peripheral portion of the tunnel junction layer 106, and only the entire region in the thickness direction of the peripheral portion of the first cladding layer 105. As a result, the peak position of the ion concentration becomes a boundary between the first cladding layer 105 and the active layer 104.

Therefore, only the peripheral portion of the third cladding layer 107, the peripheral portion of the tunnel junction layer 106, and the peripheral portion of the first cladding layer 105 are increased in resistance by ion implantation, and only the third cladding layer 107 is decreased in resistance by the subsequent annealing treatment and recovered.

According to the surface emitting laser 100-3, although the current confinement effect cannot be obtained in the active layer 104, since the ion implantation depth can be made relatively shallow at the time of forming the current confinement region CCR, the width controllability of the current confinement region CCR is excellent, and since the peak position of the ion concentration can be made farther from the tunnel junction layer 106, the characteristic change of the tunnel junction layer 106 can be further suppressed, and manufacturing can be performed with a small number of steps, so that productivity is high.

### Modification 4

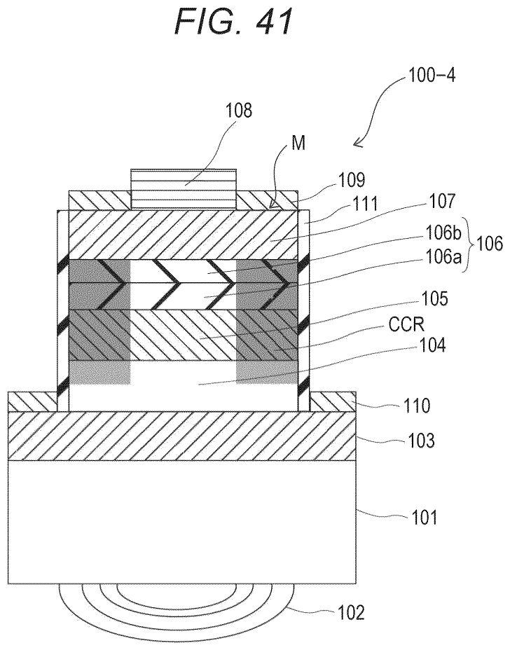

As illustrated in FIG. 41, a surface emitting laser 100-4 of Modification 4 has a similar configuration to the surface emitting laser 100 of the first embodiment except that the entire region in the thickness direction of the peripheral portion of the tunnel junction layer 106, the entire region in the thickness direction of the peripheral portion of the first cladding layer 105, and only the upper portion (portion on the tunnel junction layer 106 side) of the peripheral portion of the active layer 104 are increased in resistance. That is, in the surface emitting laser 100-4, the entire region in the thickness direction of the peripheral portion of the tunnel junction layer 106, the entire region in the thickness direction of the peripheral portion of the first cladding layer 105, and the upper portion of the peripheral portion of the active layer 104 constitute the current confinement region CCR.

The surface emitting laser 100-4 is also manufactured by the procedure of the flowchart of FIG. 2 or 21 substantially similarly to the surface emitting laser 100. Note that, also in the method for manufacturing the surface emitting laser 100-4, since ions are not caused to reach the growth substrate 101, it is not necessary to remove the growth substrate 101. Therefore, for example, instead of steps S11 to S15 in FIG. 2 and steps S21 to S25 in FIG. 21, a step (process) of forming the second reflector 102 on the growth substrate 101 is only required to be performed.

At the time of manufacturing the surface emitting laser 100-4, when ion implantation is performed from the third cladding layer 107 side with respect to the peripheral portion of the laminate or the peripheral portion of the mesa formed by etching the laminate, ion implantation energy is adjusted such that ions are implanted into the entire region in the thickness direction of the peripheral portion of the third cladding layer 107, the entire region in the thickness direction of the peripheral portion of the tunnel junction layer 106, the entire region in the thickness direction of the peripheral portion of the first cladding layer 105, and only the upper portion of the peripheral portion of the active layer 104. As a result, the peak position of the ion concentration is in the active layer 104.

Therefore, only the peripheral portion of the third cladding layer 107, the peripheral portion of the tunnel junction layer 106, the peripheral portion of the first cladding layer 105, and the upper portion of the peripheral portion of the active layer 104 are increased in resistance by ion implantation, and only the third cladding layer 107 is decreased in resistance and recovered by the subsequent annealing treatment.

According to the surface emitting laser 100-4, although the current confinement effect cannot be obtained in the lower portion of the active layer 104, since the ion implantation depth can be made relatively shallow at the time of forming the current confinement region CCR, the width controllability of the current confinement region CCR is excellent, and since the peak position of the ion concentration can be made further away from the tunnel junction layer 106, the characteristic change of the tunnel junction layer 106 can be further suppressed, and manufacturing can be performed with a small number of steps, so that productivity is high.

### Modification 5

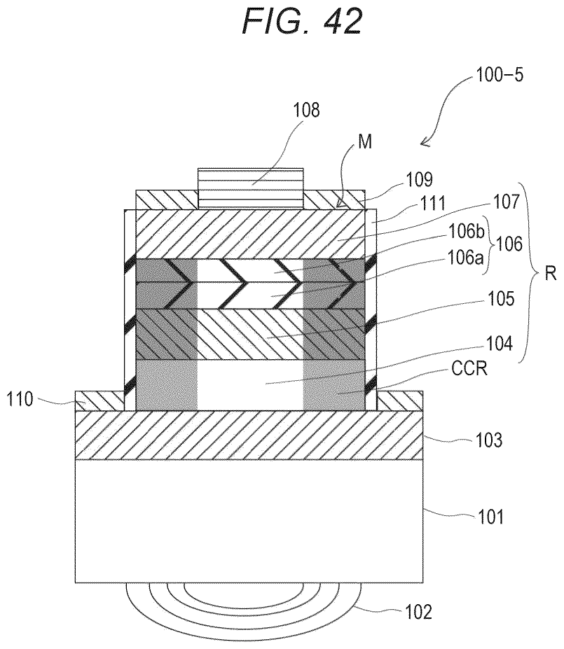

As illustrated in FIG. 42, a surface emitting laser 100-5 of Modification 5 has a similar configuration to the surface emitting laser 100 of the first embodiment except that the growth substrate 101 is used instead of the substrate 130 (reflector forming substrate).

The surface emitting laser 100-5 is also manufactured by the procedure of the flowchart of FIG. 2 or 21 substantially similarly to the surface emitting laser 100. Note that, also in the method for manufacturing the surface emitting laser 100-5, since ions are not caused to reach the growth substrate 101, it is not necessary to remove the growth substrate 101. Therefore, for example, instead of steps S11 to S15 in FIG. 2 and steps S21 to S25 in FIG. 21, a step (process) of forming the second reflector 102 on the growth substrate 101 is only required to be performed.

At the time of manufacturing the surface emitting laser 100-5, when ions are implanted from the third cladding layer 107 side into the peripheral portion of the laminate or the peripheral portion of the mesa formed by etching the laminate, the ion implantation energy is adjusted such that ions are implanted into the entire region in the thickness direction of the peripheral portion of the third cladding layer 107, the entire region in the thickness direction of the peripheral portion of the tunnel junction layer 106, the entire region in the thickness direction of the peripheral portion of the first cladding layer 105, the entire region in the thickness direction of the peripheral portion of the active layer 104, and at least only a part in the thickness direction of the peripheral portion of the second cladding layer 103. As a result, the peak position of the ion concentration becomes the inside of the second cladding layer 103 or the boundary between the second cladding layer 103 and the growth substrate 101.

Therefore, at least only a part of the peripheral portion of the third cladding layer 107, the peripheral portion of the tunnel junction layer 106, the peripheral portion of the first cladding layer 105, the peripheral portion of the active layer 104, and the peripheral portion of the second cladding layer 103 is increased in resistance by ion implantation, and at least only a part of the peripheral portion of the third cladding layer 107 and the peripheral portion of the second cladding layer 103 in the thickness direction is decreased and recovered by the subsequent annealing treatment.

According to the surface emitting laser 100-5, since the ion implantation depth can be made slightly shallow at the time of forming the current confinement region CCR, the width controllability of the current confinement region CCR is slightly excellent, and since the peak position of the ion concentration can be further moved away from the tunnel junction layer 106, the characteristic change of the tunnel junction layer 106 can be further suppressed, and the manufacturing can be performed with a small number of steps, so that the productivity is high.

### 4. Surface Emitting Laser According to Second Embodiment of Present Technology

Hereinafter, a surface emitting laser 300 according to a second embodiment of the present technology will be described.

### (1) Configuration of Surface Emitting Laser

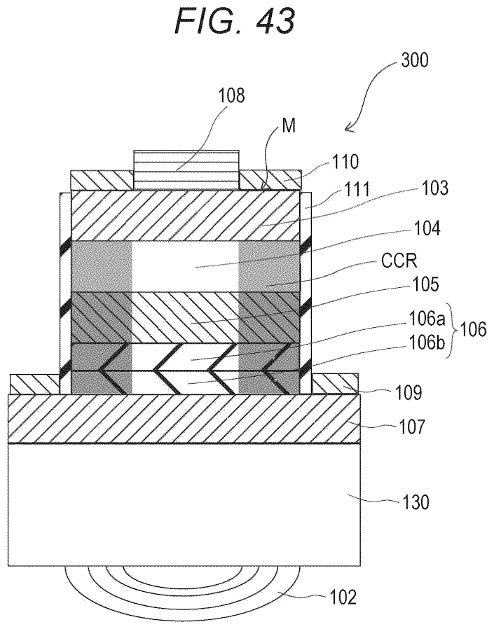

As illustrated in FIG. 43, the surface emitting laser 300 of the second embodiment has a similar configuration to the surface emitting laser 100 of the first embodiment except that the resonator has a vertically inverted configuration and the conductivity type is partially switched.

More specifically, in the surface emitting laser 300, the third cladding layer 107, the tunnel junction layer 106, the first cladding layer 105, the active layer 104, and the second cladding layer 103 are arranged in this order from the substrate 130 side on the substrate 130.

In the surface emitting laser 300, the first cladding layer 105 is a p-type semiconductor layer (for example, a p-InP layer), the second cladding layer 103 is an n-type semiconductor layer (for example, an n-InP layer), and the third cladding layer 107 is an n-type semiconductor layer (for example, an n-InP layer).

In the surface emitting laser 300, the n-type semiconductor region 106b is located on the substrate 130 side (lower side) of the p-type semiconductor region 106a in the tunnel junction layer 106.

In the surface emitting laser 300, the anode electrode 109 is provided on the third cladding layer 107, and a current path exists in the third cladding layer 107, and the cathode electrode 110 is provided on the top portion of the mesa M (for example, the first cladding layer 103), and a current path exists in the second cladding layer 103.

### (2) Method for Manufacturing Surface Emitting Laser

Hereinafter, a method for manufacturing the surface emitting laser 300 will be described.

Similarly to the surface emitting laser 100, the surface emitting laser 300 is also manufactured by the procedure of the flowchart of FIGS. 2 or 21. In the method for manufacturing the surface emitting laser 300, a laminate generation process 2 as an example of a laminate generation process is performed.

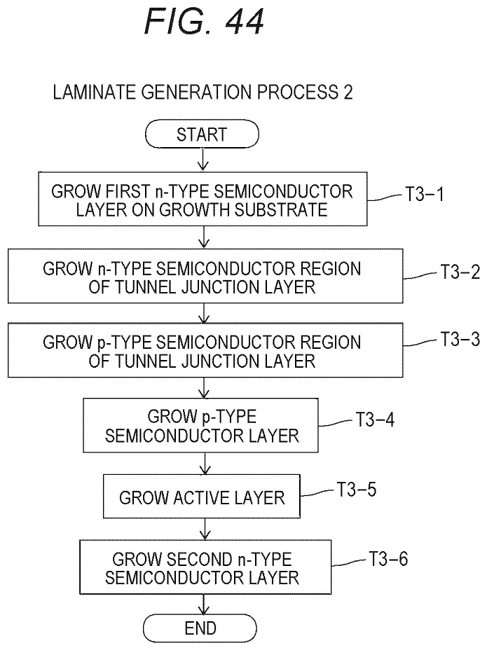

Hereinafter, the laminate generation process 2 will be described with reference to the flowchart (steps T3-1 to T3-6) of FIG. 44.

In the first step T3-1, as an example, the third cladding layer 107 (for example, an n-InP layer) is grown as a first type semiconductor layer on the growth substrate 101 (for example, an InP substrate).

In the next step T3-2, the n-type semiconductor region 106b of the tunnel junction layer 106 is grown on the third cladding layer 107.

In the next step T3-3, the p-type semiconductor region 106a of the tunnel junction layer 106 is grown on the n-type semiconductor region 106b.

In the next step T3-4, the first cladding layer 105 is grown as a p-type semiconductor layer (for example, a p-InP layer) on the p-type semiconductor region 106a.

In the next step T3-5, the active layer 104 is grown on the first cladding layer 105.

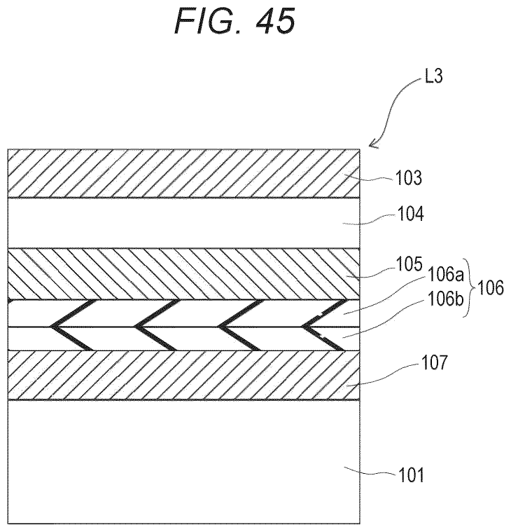

In the final step T3-6, the second cladding layer 103 (for example, an n-InP layer) is grown as a second n-type semiconductor layer on the active layer 104. As a result, a laminate L3 (see FIG. 45) is generated.

Next, ion implantation is performed such that ions reach the growth substrate 101 from the second cladding layer 103 side with respect to the peripheral portion of the laminate L3 or the peripheral portion of the mesa formed by etching the laminate L3. As a result, a peripheral portion of the second cladding layer 103, a peripheral portion of the active layer 104, a peripheral portion of the first cladding layer 105, a peripheral portion of the tunnel junction layer 106, a peripheral portion of the third cladding layer 107, and a peripheral portion of the growth substrate 101 have high resistance. Thereafter, an annealing treatment is performed, and the peripheral portion of the second cladding layer 103 which is an n-type semiconductor layer and the peripheral portion of the third cladding layer 107 which is an n-type semiconductor layer are reduced in resistance and recovered, while the peripheral portion of the tunnel junction layer 106, the peripheral portion of the active layer 104, and the peripheral portion of the first cladding layer 105 which is a p-type semiconductor layer remain increased in resistance and are not recovered.

### (3) Effects of Surface Emitting Laser and Method for Manufacturing the Same

According to the surface emitting laser 300, similar effects to those of the surface emitting laser 100 of the first embodiment can be obtained.

According to the method for manufacturing the surface emitting laser 300, similar effects to those of the method for manufacturing the surface emitting laser 100 are obtained.

### 5. Surface Emitting Lasers According to Modifications 1 to 4 of Second Embodiment of Present Technology

Hereinafter, surface emitting lasers 300-1 to 300-4 according to Modification 1 to 4 of the second embodiment of the present technology will be described.

### Modification 1

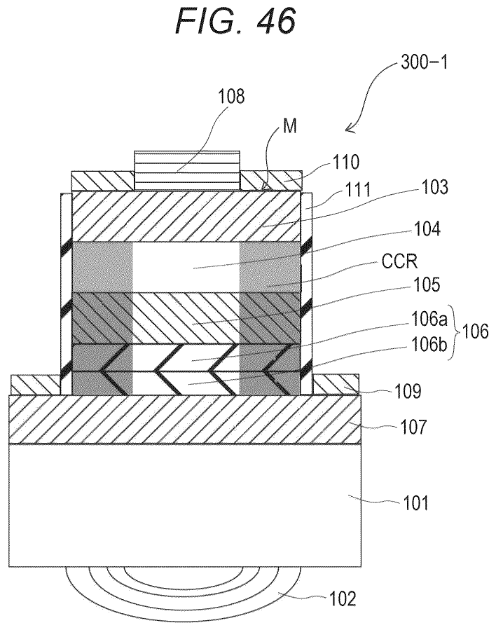

As illustrated in FIG. 46, the surface emitting laser 300-1 of Modification 1 has a similar configuration to the surface emitting laser 300 of the second embodiment except that the growth substrate 101 is provided instead of the substrate 130 (reflector forming substrate).

The surface emitting laser 300-1 is manufactured by the procedure of the flowchart of FIG. 2 or 21 substantially similarly to the surface emitting laser 300. Note that, in the method for manufacturing the surface emitting laser 300-1, since ions are not caused to reach the growth substrate 101, it is not necessary to remove the growth substrate 101. Therefore, for example, instead of steps S11 to S15 in FIG. 2 and steps S21 to S25 in FIG. 21, a step (process) of forming the second reflector 102 on the growth substrate 101 is only required to be performed.

At the time of manufacturing the surface emitting laser 300-1, when ions are implanted into the peripheral portion of the laminate L3 or the peripheral portion of the mesa M formed by etching the laminate L3 from the second cladding layer 103 side, the ion implantation energy is adjusted such that ions are implanted into the entire region of the peripheral portion of the second cladding layer 103 in the thickness direction, the entire region of the peripheral portion of the active layer 104 in the thickness direction, the entire region of the peripheral portion of the first cladding layer 105 in the thickness direction, the entire region of the peripheral portion of the tunnel junction layer 106 in the thickness direction, and at least only a part of the peripheral portion of the third cladding layer 107 in the thickness direction. As a result, the peak position of the ion concentration is in the third cladding layer 107 or in the vicinity of the boundary between the third cladding layer 107 and the growth substrate 101.

Therefore, at least only a part in the thickness direction of the peripheral portion of the second cladding layer 103, the peripheral portion of the active layer 104, the peripheral portion of the first cladding layer 105, the peripheral portion of the tunnel junction layer 106, and the peripheral portion of the third cladding layer 107 is increased by ion implantation, and at least only a part in the thickness direction of the peripheral portion of the second cladding layer 103 and the peripheral portion of the third cladding layer 107 is decreased and recovered by the subsequent annealing treatment.

According to the surface emitting laser 300-1, since the ion implantation depth can be made slightly shallow at the time of forming the current confinement region CCR, the width controllability of the current confinement region CCR is slightly excellent, and since the peak position of the ion concentration can be further moved away from the tunnel junction layer 106, the characteristic change of the tunnel junction layer 106 can be further suppressed, and the manufacturing can be performed with a small number of steps, so that the productivity is high.

### Modification 2

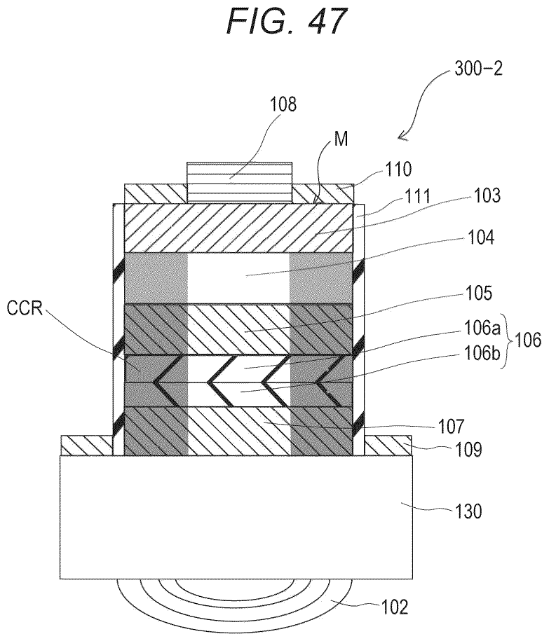

As illustrated in FIG. 47, the surface emitting laser 300-2 of Modification 2 has a similar configuration to the surface emitting laser 300 of the second embodiment except that the conductivity type is partially changed, the third cladding layer 107 constitutes the bottom portion of the mesa M, and the resistance of the peripheral portion of the third cladding layer 107 is increased.

More specifically, in the surface emitting laser 300-2, the first cladding layer 105 is a p-type semiconductor layer (for example, a p-InP layer), the second cladding layer 103 is an n-type semiconductor layer (for example, an n-InP layer), and the third cladding layer 107 is a p-type semiconductor layer (for example, a p-InP layer).

In the surface emitting laser 300-2, the anode electrode 109 is provided on the upper surface of the substrate 130 which is a conductive substrate, a current path exists in the substrate 130, and the cathode electrode 110 is provided on the top portion of the mesa M (for example, the second cladding layer 103).

Hereinafter, a method for manufacturing the surface emitting laser 300-2 will be described.

Similarly to the surface emitting laser 300, the surface emitting laser 300-2 is also manufactured by the procedure of the flowchart of FIG. 2 or 21. In the method for manufacturing the surface emitting laser 300-2, a laminate generation process 3 as an example of the laminate generation process is performed.

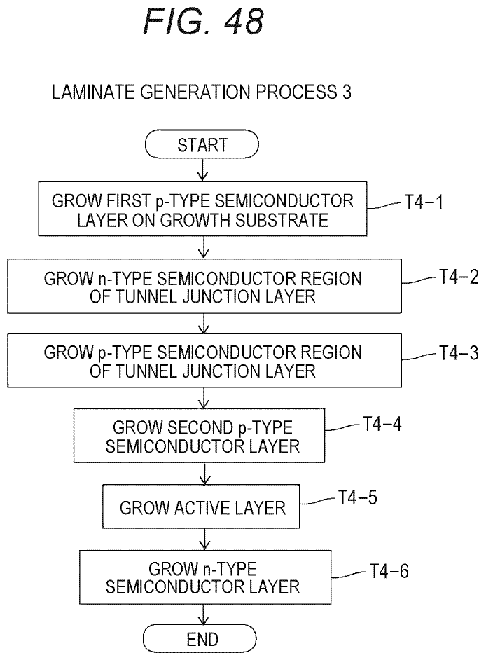

The laminate generation process 3 will be described below with reference to the flowchart (steps T4-1 to T4-6) of FIG. 48.

In the first step T4-1, as an example, the third cladding layer 107 (for example, a p-InP layer) is grown as a first p-type semiconductor layer on the growth substrate 101 (for example, an InP substrate).

In the next step T4-2, the n-type semiconductor region 106b of the tunnel junction layer 106 is grown on the third cladding layer 107.

In the next step T4-3, the p-type semiconductor region 106a of the tunnel junction layer 106 is grown on the n-type semiconductor region 106b.

In the next step T4-4, the first cladding layer 105 (for example, a p-InP layer) is grown as a second p-type semiconductor layer on the p-type semiconductor region 106a.

In the next step T4-5, the active layer 104 is grown on the second p-type semiconductor layer.

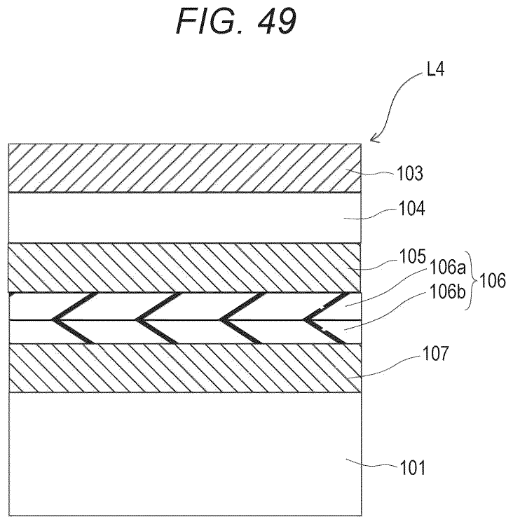

In the final step T4-6, the second cladding layer 103 (for example, an n-InP layer) is grown as an n-type semiconductor layer on the active layer 104. As a result, a laminate L4 (see FIG. 49) is generated.

Next, ion implantation is performed such that ions reach the growth substrate 101 from the second cladding layer 103 side with respect to the peripheral portion of the laminate L4 or the peripheral portion of the mesa formed by etching the laminate L4. As a result, a peripheral portion of the second cladding layer 103, a peripheral portion of the active layer 104, a peripheral portion of the first cladding layer 105, a peripheral portion of the tunnel junction layer 106, a peripheral portion of the third cladding layer 107, and a peripheral portion of the growth substrate 101 have high resistance. Thereafter, an annealing treatment is performed, and only the peripheral portion of the second cladding layer 103 which is an n-type semiconductor layer is reduced in resistance and recovered, while the peripheral portion of the active layer 104, the peripheral portion of the first cladding layer 105, the peripheral portion of the tunnel junction layer 106, and the peripheral portion of the third cladding layer 107 remain high in resistance and are not recovered.

According to the surface emitting laser 300-2, similar effects to those of the surface emitting laser 300 of the second embodiment can be obtained.

According to the method for manufacturing the surface emitting laser 300-2, similar effects to those of the method for manufacturing the surface emitting laser 300 are obtained.

### Modification 3

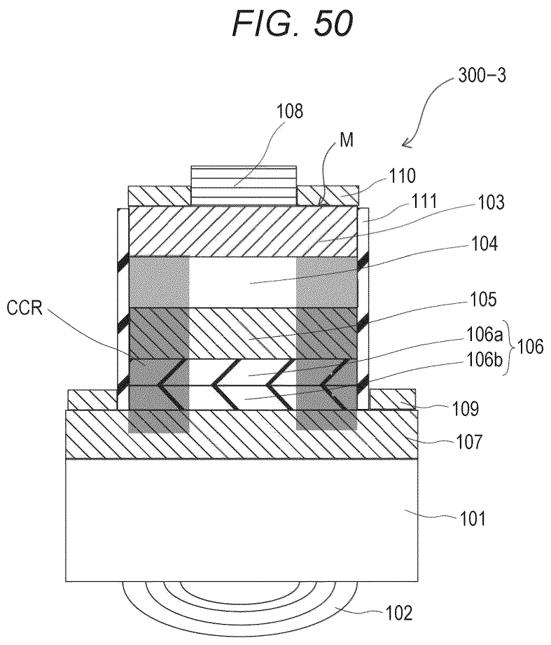

As illustrated in FIG. 50, the surface emitting laser 300-3 of Modification 3 has a substantially similar configuration to the surface emitting laser 300-2 of Modification 2 except that the conductivity type is partially changed and the tunnel junction layer 106 forms the bottom portion of the mesa M. In the surface emitting laser 300-3, the anode electrode 109 is provided on the third cladding layer 107.

Hereinafter, a method for manufacturing the surface emitting laser 300-3 will be briefly described.

The surface emitting laser 300-3 is also manufactured by the procedure of the flowchart of FIGS. 2 or 21 substantially similarly to the surface emitting laser 300-2. Note that, in the method for manufacturing the surface emitting laser 300-3, since ions are not caused to reach the growth substrate 101, it is not necessary to remove the growth substrate 101. Therefore, for example, instead of steps S11 to S15 in FIG. 2 and steps S21 to S25 in FIG. 21, a step (process) of forming the second reflector 102 on the growth substrate 101 is only required to be performed.

In the method for manufacturing the surface emitting laser 300-3, first, a laminate generation process 4 as an example of the laminate generation process is performed. Next, ion implantation is performed so that ions reach the third cladding layer 107 from the second cladding layer 103 side with respect to the peripheral portion of the laminate L4 generated in the laminate generation process 4 or the peripheral portion of the mesa M formed by etching the laminate L4. As a result, a peripheral portion of the second cladding layer 103, a peripheral portion of the active layer 104, a peripheral portion of the first cladding layer 105, a peripheral portion of the tunnel junction layer 106, and an upper portion of a peripheral portion of the third cladding layer 107 (a portion on the tunnel junction layer 106 side) have high resistance. Thereafter, an annealing treatment is performed, and the peripheral portion of the second cladding layer 103 is recovered by reducing the resistance, while the peripheral portion of the active layer 104, the peripheral portion of the first cladding layer 105, the peripheral portion of the tunnel junction layer 106, and the upper portion of the peripheral portion of the third cladding layer 107 remain high in resistance and are not recovered.

According to the surface emitting laser 300-3, although the current confinement effect cannot be obtained in the lower portion of the peripheral portion of the third cladding layer 107, since the ion implantation depth can be made slightly shallow at the time of forming the current confinement region CCR, the width controllability of the current confinement region CCR is slightly excellent, and manufacturing can be performed with a small number of steps, so that productivity is high.

### Modification 4

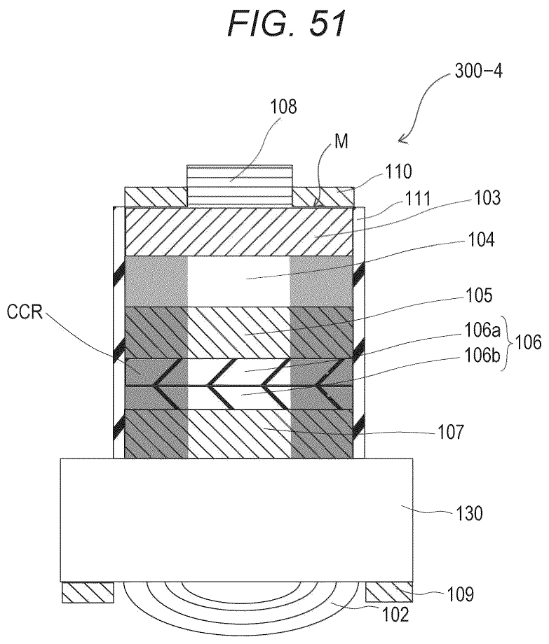

As illustrated in FIG. 51, the surface emitting laser 300-4 of Modification 4 has a substantially similar configuration to the surface emitting laser 300-2 of Modification 2 except that the anode electrode 109 is provided on the back surface (lower surface) of the conductive substrate 130.

The surface emitting laser 300-4 is manufactured by the procedure of the flowchart of FIGS. 2 or 21 substantially similarly to the surface emitting laser 300-2.

The surface emitting laser 300-4 has similar effects to those of the surface emitting laser 300-2.

### 6. Surface Emitting Laser According to Third Embodiment of Present Technology

Hereinafter, a surface emitting laser 400 according to a third embodiment of the present technology will be described.

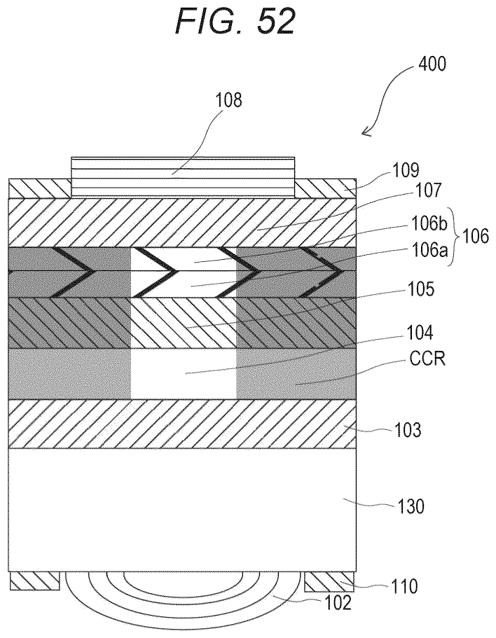

As illustrated in FIG. 52, the surface emitting laser 400 of the third embodiment has a similar configuration to the surface emitting laser 100 of the first embodiment except that it is a gain guide type without the mesa M.

In the surface emitting laser 400, for example, the cathode electrode 110 is provided in a frame shape (for example, an annular shape) on the back surface (lower surface) of the conductive substrate 130 so as to surround the second reflector 102.

Hereinafter, a method for manufacturing the surface emitting laser 400 will be described.

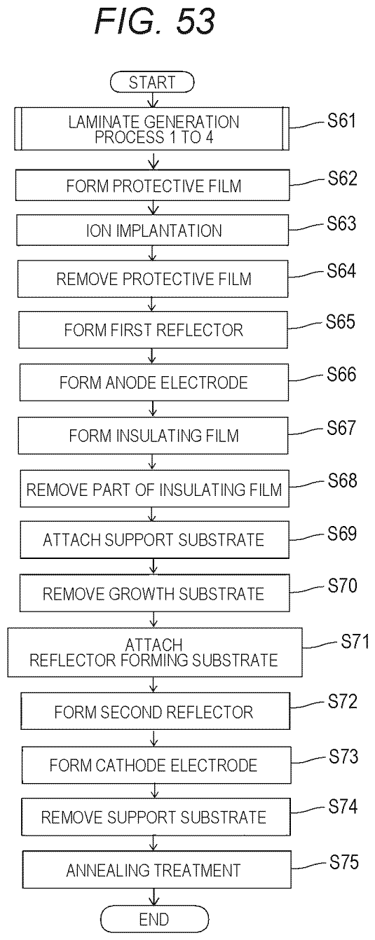

The surface emitting laser 400 is manufactured by the procedure of the flowchart (steps S61 to S75) of FIG. 53. Each step in the flowchart of FIG. 53 is substantially the same as the corresponding step in the flowcharts of FIGS. 2 and 21. However, in the flowchart of FIG. 53, the step of forming the mesa M is not included, and the step of forming the cathode electrode 110 (step S73) is executed between a step of forming the second reflector (step S72) and a step of removing the support substrate 120 (step S74).

In the method for manufacturing the surface emitting laser 400, in step S61, the laminate generation process 1 as an example of the laminate generation process is performed.

Next, ion implantation is performed so that ions reach the growth substrate 101 from the third cladding layer 107 side with respect to the peripheral portion of the laminate L1. As a result, a peripheral portion of the third cladding layer 107, a peripheral portion of the tunnel junction layer 106, a peripheral portion of the first cladding layer 105, a peripheral portion of the active layer 104, a peripheral portion of the second cladding layer 103, and a peripheral portion of the growth substrate 101 have high resistance. Thereafter, an annealing treatment is performed, and the peripheral portion of the third cladding layer 107 which is an n-type semiconductor layer and the peripheral portion of the second cladding layer 103 which is an n-type semiconductor layer are reduced in resistance and recovered, while the peripheral portion of the tunnel junction layer 106, the peripheral portion of the first cladding layer 105 which is a p-type semiconductor layer, and the peripheral portion of the active layer 104 remain increased in resistance and are not recovered.

According to the surface emitting laser 400, similar effects to those of the surface emitting laser 100 of the first embodiment can be obtained.

According to the method for manufacturing the surface emitting laser 400, effects similar to those of the method for manufacturing the surface emitting laser 100 are obtained, and since the mesa M is not formed, manufacturing can be performed with a small number of steps, and productivity is high.

Note that, in step S61 of the flowchart of FIG. 53, by performing the laminate generation process 2, a surface emitting laser having a layer configuration similar to that of the surface emitting laser 300 of the second embodiment can be manufactured. In step S61 of the flowchart of FIG. 53, by performing the laminate generation process 3, a surface emitting laser having a layer configuration similar to that of the surface emitting laser 300-2 of Modification 2 of the second embodiment can be manufactured.

### 7. Modification of Present Technology

The present technology is not limited to each of the embodiments and modifications described above, and various modifications can be made.

For example, in each of the above embodiments and modifications, the cladding layer constituted by an InP-based compound semiconductor has been described as an example, but instead of this, the cladding layer may be constituted by, for example, a GaAs compound semiconductor, an AlGaAs-based compound semiconductor, or the like.

For example, each of the p-type semiconductor region 106a and the n-type semiconductor region 106b may be constituted by, for example, any of an InP-based compound semiconductor, an AlGaInAs-based compound semiconductor, and an AlGaInSbAs-based compound semiconductor.

Each of the first and second reflectors 108 and 102 may be a semiconductor multilayer film reflector constituted by a compound of two or more elements of Al, Ga, and As.

Some of the configurations of the surface emitting laser of each of the above embodiments and modifications may be combined within a range in which they do not contradict each other.

In each of the embodiments and modifications described above, the material, conductivity type, thickness, width, length, shape, size, arrangement, and the like of each component constituting the surface emitting laser can be appropriately changed within a range functioning as the surface emitting laser.

### 8. Application Example to Electronic Device

The technology according to the present disclosure (the present technology) can be applied to various products (electronic devices). For example, the technology according to the present disclosure may be implemented as a device mounted on any type of mobile body such as an automobile, an electric vehicle, a hybrid electric vehicle, a motorcycle, a bicycle, a personal mobility, an airplane, a drone, a ship, and a robot.

The surface emitting laser according to the present technology can also be applied as, for example, a light source of a device that forms or displays an image by laser light (for example, a laser printer, a laser copier, a projector, a head-mounted display, a head-up display, or the like).

### 9. Example in Which Surface Emitting Laser Is Applied to Distance Measuring Device

Hereinafter, application examples of the surface emitting laser according to each of the embodiments and modifications described above will be described.

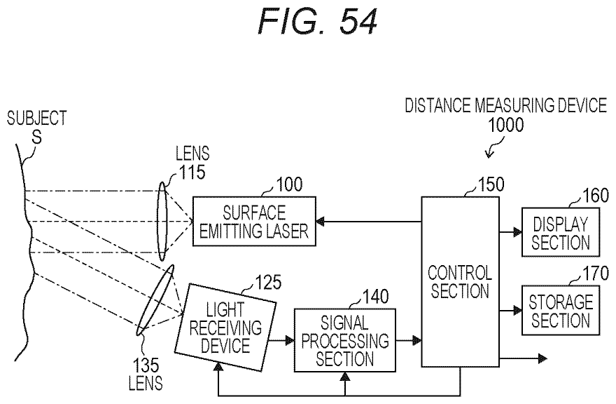

FIG. 54 illustrates an example of a schematic configuration of a distance measuring device 1000 including the surface emitting laser 100 as an example of an electronic device according to the present technology. The distance measuring device 1000 measures the distance to a subject S by a time of flight (TOF) method. The distance measuring device 1000 includes the surface emitting laser 100 as a light source. The distance measuring device 1000 includes, for example, the surface emitting laser 100, a light receiving device 125, lenses 115 and 135, a signal processing section 140, a control section 150, a display section 160, and a storage section 170.

The light receiving device 125 detects light reflected by the subject S. The lens 115 is a lens for collimating the light emitted from the surface emitting laser 100, and is a collimating lens. The lens 135 is a lens for condensing light reflected by the subject S and guiding the light to the light receiving device 125, and is a condenser lens.

The signal processing section 140 is a circuit for generating a signal corresponding to a difference between a signal input from the light receiving device 125 and a reference signal input from the control section 150. The control section 150 includes, for example, a time to digital converter (TDC). The reference signal may be a signal input from the control section 150, or may be an output signal of a detecting section that directly detects the output of the surface emitting laser 100. The control section 150 is, for example, a processor that controls the surface emitting laser 100, the light receiving device 125, the signal processing section 140, the display section 160, and the storage section 170. The control section 150 is a circuit that measures a distance to the subject S on the basis of a signal generated by the signal processing section 140. The control section 150 generates a video signal for displaying information about the distance to the subject S, and outputs the video signal to the display section 160. The display section 160 displays information about the distance to the subject S on the basis of the video signal input from the control section 150. The control section 150 stores information about the distance to the subject S in the storage section 170.

In the present application example, instead of the surface emitting laser 100, any one of the above surface emitting lasers 100-1 to 100-5, 200, 200-1 to 200-5, 300, 300-1 to 300-4, and 400 can be applied to the distance measuring device 1000.

### 10. Example in Which Distance Measuring Device Is Mounted on Mobile Body

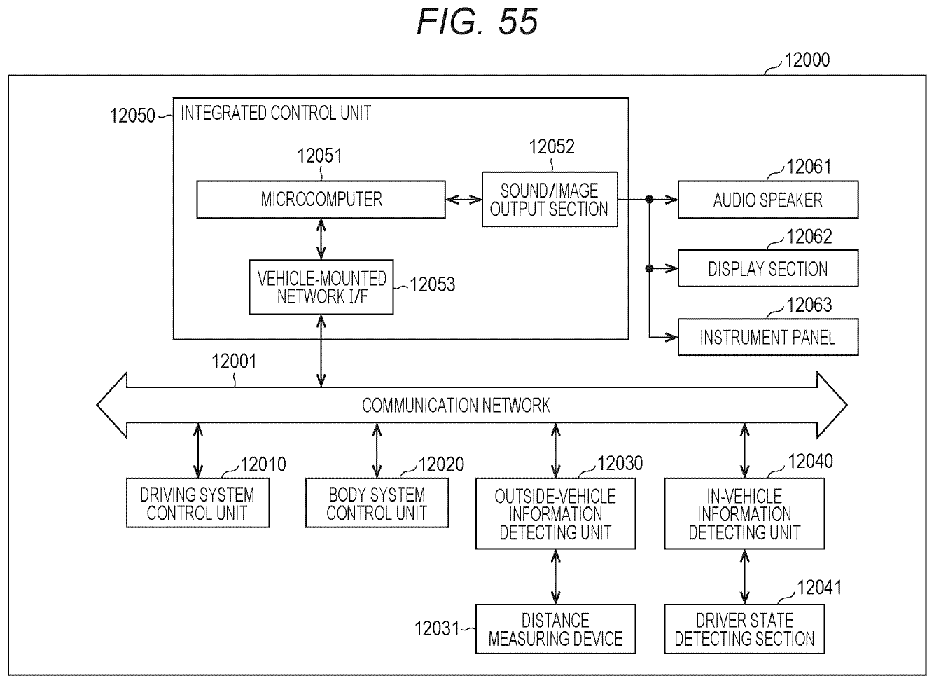

FIG. 55 is a block diagram illustrating a schematic configuration example of a vehicle control system which is an example of a mobile body control system to which the technology according to the present disclosure may be applied.

A vehicle control system 12000 includes a plurality of electronic control units connected to each other via a communication network 12001. In the example illustrated in FIG. 55, the vehicle control system 12000 is provided with a driving system control unit 12010, a body system control unit 12020, an outside-vehicle information detecting unit 12030, an in-vehicle information detecting unit 12040, and an integrated control unit 12050. Further, a microcomputer 12051, a sound/image output section 12052, and a vehicle-mounted network interface (I/F) 12053 are depicted as a functional configuration of the integrated control unit 12050.

The driving system control unit 12010 controls an operation of devices related to a drive system of a vehicle in accordance with various programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls an operation of various devices mounted on a vehicle body in accordance with various programs. For example, the body system control unit 12020 functions as a control device for a keyless entry system, a smart key system, a power window device, or various kinds of lamps such as a headlamp, a backup lamp, a brake lamp, a turn signal, or a fog lamp. In this case, radio waves transmitted from a mobile device as an alternative to a key or signals of various kinds of switches can be input to the body system control unit 12020. The body system control unit 12020 receives an input of these radio waves or signals, and controls a door lock device, a power window device, a lamp, and the like of the vehicle.

The outside-vehicle information detecting unit 12030 detects information about the outside of the vehicle including the vehicle control system 12000. For example, a distance measuring device 12031 is connected to the outside-vehicle information detecting unit 12030. The distance measuring device 12031 includes the above-described distance measuring device 1000. The outside-vehicle information detecting unit 12030 causes the distance measuring device 12031 to measure a distance to an object (subject S) outside the vehicle, and acquires distance data obtained by the measurement. The outside-vehicle information detecting unit 12030 may perform object detection processing of a person, a vehicle, an obstacle, a sign, or the like on the basis of the acquired distance data.

The in-vehicle information detecting unit 12040 detects information about the inside of the vehicle. For example, a driver state detecting section 12041 for detecting the state of a driver is connected to the in-vehicle information detecting unit 12040. The driver state detecting section 12041, for example, includes a camera that images the driver. On the basis of detection information input from the driver state detecting section 12041, the in-vehicle information detecting unit 12040 may calculate the degree of fatigue of the driver or the degree of concentration of the driver or may determine whether the driver is awake.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a lane deviation warning of the vehicle, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle acquired by the outside-vehicle information detecting unit 12030. For example, the microcomputer 12051 can perform cooperative control intended to prevent glare by controlling the headlamp so as to switch from a high beam to a low beam or the like, for example, according to the position of a preceding vehicle or an oncoming vehicle detected by the outside-vehicle information detecting unit 12030.

The sound/image output section 12052 transmits an output signal of at least one of a sound or an image to an output device capable of visually or auditorily notifying an occupant of the vehicle or the outside of the vehicle of information. In the example in FIG. 55, as the output device, an audio speaker 12061, a display section 12062, and an instrument panel 12063 are illustrated. The display section 12062 may, for example, include at least one of an on-board display or a head-up display.

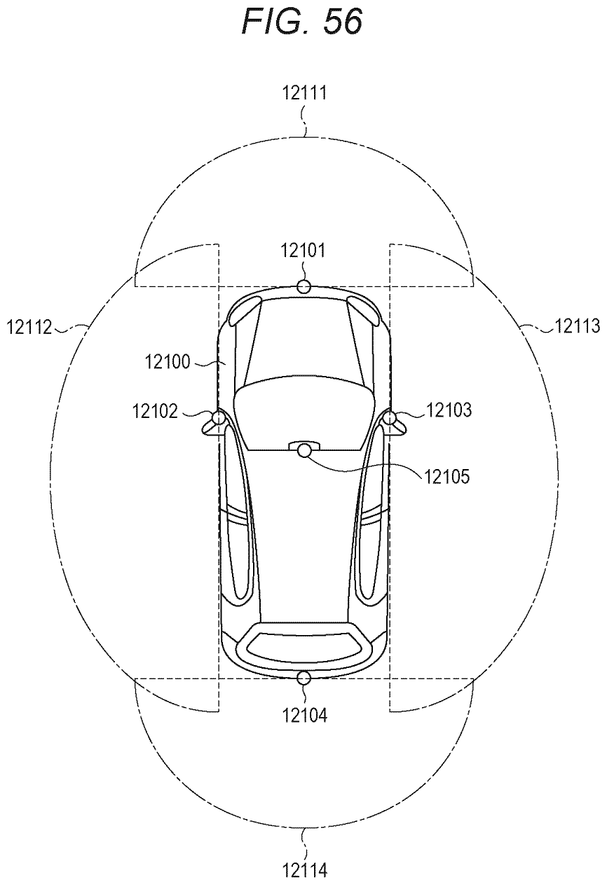

FIG. 56 is a view illustrating an example of an installation position of the distance measuring device 12031.

In FIG. 56, vehicle 12100 includes distance measuring devices 12101, 12102, 12103, 12104, and 12105 as the distance measuring device 12031.

The distance measuring devices 12101, 12102, 12103, 12104, and 12105 are provided at positions such as, for example, a front nose, sideview mirrors, a rear bumper, a back door, and an upper portion of a windshield in a vehicle cabin, of the vehicle 12100. The distance measuring device 12101 provided on the front nose and the distance measuring device 12105 provided on the upper portion of the windshield in the vehicle cabin mainly acquire data of the front side of the vehicle 12100. The distance measuring devices 12102 and 12103 provided at the sideview mirrors mainly acquire data on the sides of the vehicle 12100. The distance measuring device 12104 provided on the rear bumper or the back door mainly acquires data behind the vehicle 12100. The data of the front side acquired by the distance measuring devices 12101 and 12105 is mainly used for detecting a preceding vehicle, a pedestrian, an obstacle, a traffic light, a traffic sign, or the like.

Note that FIG. 56 illustrates an example of detection ranges of the distance measuring devices 12101 to 12104. A detection range 12111 indicates a detection range of the distance measuring device 12101 provided on the front nose, detection ranges 12112 and 12113 indicate detection ranges of the distance measuring devices 12102 and 12103 provided at the sideview mirrors, respectively, and a detection range 12114 indicates a detection range of the distance measuring device 12104 provided on the rear bumper or the back door.

For example, the microcomputer 12051 can determine a distance to each three-dimensional object within the detection ranges 12111 to 12114 and a temporal change in the distance (a relative speed with respect to the vehicle 12100) on the basis of the distance data obtained from the distance measuring devices 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Moreover, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving, in which the vehicle travels automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and the like, and other three-dimensional objects on the basis of the distance data obtained from the distance measuring devices 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is higher than or equal to a set value and there is thus a possibility of collision, the microcomputer 12051 can outputs a warning to the driver via the audio speaker 12061 or the display section 12062 and perform forced deceleration or avoidance steering via the driving system control unit 12010 to perform driving assistance for collision avoidance.

An example of the mobile body control system to which the technology according to the present disclosure can be applied has been described above. The technology according to the present disclosure can be applied to the distance measuring device 12031 among the configurations described above.

Furthermore, the present technology can also have the following configurations.

(1) A surface emitting laser including:
first and second reflectors; and
a resonator disposed between the first and second reflectors, the resonator including an active layer and a tunnel junction layer,
in which, in the resonator, a peripheral portion has higher resistance than a central portion at least in an entire region in a thickness direction of the tunnel junction layer.

(2) The surface emitting laser according to (1), in which the resonator includes a cladding layer between the tunnel junction layer and the active layer, and in the cladding layer, at least a peripheral portion of a portion on a side of the tunnel junction layer has higher resistance than a central portion.

(3) The surface emitting laser according to (1) or (2), in which the cladding layer is a p-type semiconductor layer.

(4) The surface emitting laser according to (2) or (3), in which the cladding layer is constituted by a p-type InP compound semiconductor.

(5) The surface emitting laser according to any one of (1) to (4), in which in the active layer, at least a peripheral portion of a portion on a side of the tunnel junction layer has higher resistance than a central portion.

(6) The surface emitting laser according to any one of (1) to (5), in which the resonator includes another cladding layer on a side of the active layer opposite to a side of the tunnel junction layer, and in the another cladding layer, a central portion and a peripheral portion have lower resistance than a peripheral portion of the tunnel junction layer.

(7) The surface emitting laser according to (6), in which an electrode is provided on the another cladding layer.

(8) The surface emitting laser according to (6) or (7), in which the another cladding layer is an n-type semiconductor layer.

(9) The surface emitting laser according to any one of (6) to (8), in which the another cladding layer is constituted by an n-type InP compound semiconductor.

(10) The surface emitting laser according to any one of (1) to (9), in which the resonator includes further another cladding layer on a side of the tunnel junction layer opposite to a side of the active layer, and in the further another cladding layer, a central portion and a peripheral portion have lower resistance than a peripheral portion of the tunnel junction layer.

(11) The surface emitting laser according to (10), in which an electrode is provided on the further another cladding layer.

(12) The surface emitting laser according to (10) or (11), in which the further another cladding layer is an n-type semiconductor layer.

(13) The surface emitting laser according to any one of (10) to (12), in which the cladding layer is constituted by an n-type InP compound semiconductor.

(14) The surface emitting laser according to any one of (1) to (13), in which a peripheral portion of the resonator is increased in resistance by ion implantation at least in an entire region in a thickness direction of the tunnel junction layer.

(15) The surface emitting laser according to (14), in which an impurity concentration in the ion implantation is less than 1 10¹⁹ cm⁻³. (16) The surface emitting laser according to (14) or (15), in which impurity in the ion implantation includes at least one of H, B, C, or O.

(17) The surface emitting laser according to any one of (1) to (16), in which the tunnel junction layer includes a p-type semiconductor region and an n-type semiconductor region, and each of the p-type semiconductor region and the n-type semiconductor region is constituted by any of an InP-based compound semiconductor, an AlGaInAs-based compound semiconductor, and an AlGaInSbAs-based compound semiconductor.

(18) The surface emitting laser according to any one of (1) to (17), further including a substrate disposed between the resonator and a reflector closer to the active layer than the tunnel junction layer among the first and second reflectors, in which the reflector is a concave multilayer film reflector.

(19) The surface emitting laser according to (18), in which a thermal conductivity of the substrate is 40 W/m·K or more.

(20) The surface emitting laser according to (18) or (19), in which the substrate is constituted by any of GaAs, Si, and SiC.

(21) The surface emitting laser according to any one of (18) to (20), in which the reflector is a semiconductor multilayer film reflector constituted by a compound of two or more elements of Al, Ga, and As.

(22) A surface emitting laser array including a plurality of the surface emitting laser according to any one of (1) to (21).

(23) An electronic device including the surface emitting laser according to any one of (1) to (21).

(24) An electronic device including the surface emitting laser array according to (22).

(25) A method for manufacturing a surface emitting laser, the method including:
a step of stacking a resonator including an active layer and a tunnel junction layer on a first substrate to generate a laminate; and
a step of implanting ions into a peripheral portion of the resonator to make resistance of the peripheral portion higher than resistance of a central portion at least in an entire region in a thickness direction of the tunnel junction layer.

(26) The method for manufacturing a surface emitting laser according to (25), in which the resonator includes a cladding layer between the tunnel junction layer and the active layer, and in the step of increasing the resistance, resistance of a peripheral portion of at least a portion of the cladding layer on a side of the tunnel junction layer is also increased.

(27) The method for manufacturing a surface emitting laser according to (25) or (26), in which, in the step of increasing the resistance, resistance of a peripheral portion of at least a portion of the active layer on a side of the tunnel junction layer is also increased.

(28) The surface emitting laser according to any one of (25) to (27), in which the resonator includes a cladding layer on a side of the active layer opposite to a side of the tunnel junction layer, and in the step of increasing the resistance, resistance of a peripheral portion of at least a portion of the cladding layer on a side of the tunnel junction layer is also increased.

(29) The method for manufacturing a surface emitting laser according to any one of (25) to (28), in which ions are caused to reach the first substrate in the step of increasing the resistance.

(30) The method for manufacturing a surface emitting laser according to any one of (25) to (29), further including: after the step of increasing the resistance, a step of bonding a support substrate to a surface of the laminate on a side of the resonator; and a step of removing the first substrate from the laminate.

(31) The method for manufacturing a surface emitting laser according to (30), further including: a step of bonding a second substrate to a surface of the laminate from which the first substrate has been removed; and a step of forming a reflector on the second substrate.

(32) The method for manufacturing a surface emitting laser according to any one of (25) to (31), in which the resonator includes an n-type semiconductor layer on a side of the tunnel junction layer opposite to a side of the active layer, and in the step of increasing the resistance, resistance of a peripheral portion of at least a portion of the n-type semiconductor layer on a side of the tunnel junction layer is also increased.

(33) The method for manufacturing a surface emitting laser according to (32), further including, after the step of increasing the resistance, a step of performing an annealing treatment on the laminate to reduce resistance of at least a peripheral portion of a portion of the n-type semiconductor layer on a side of the tunnel junction layer.

(34) The method for manufacturing a surface emitting laser according to any one of (25) to (33), in which the resonator includes a p-type semiconductor layer on a side of the tunnel junction layer opposite to a side of the active layer, and in the step of increasing the resistance, resistance of a peripheral portion of at least a portion of the p-type semiconductor layer on a side of the tunnel junction layer is also increased.

(35) The method for manufacturing a surface emitting laser according to any one of (25) to (34), in which the resonator includes a p-type semiconductor layer between the tunnel junction layer and the active layer, and in the step of increasing the resistance, resistance of a peripheral portion of at least a portion of the p-type semiconductor layer on a side of the tunnel junction layer is also increased.

(36) The method for manufacturing a surface emitting laser according to any one of (25) to (35), in which the resonator includes an n-type semiconductor layer between the tunnel junction layer and the active layer, and in the step of increasing the resistance, resistance of a peripheral portion of at least a portion of the n-type semiconductor layer on a side of the tunnel junction layer is also increased.

(37) The method for manufacturing a surface emitting laser according to (36), further including, after the step of increasing the resistance, a step of performing an annealing treatment on the laminate to reduce resistance of at least a peripheral portion of a portion of the n-type semiconductor layer on a side of the tunnel junction layer.

(38) The method for manufacturing a surface emitting laser according to any one of (25) to (37), in which the resonator includes an n-type semiconductor layer on a side of the active layer opposite to a side of the tunnel junction layer, and in the step of increasing the resistance, resistance of a peripheral portion of at least a portion of the n-type semiconductor layer on a side of the active layer is also increased.

(39) The method for manufacturing a surface emitting laser according to (38), further including, after the step of increasing the resistance, a step of performing an annealing treatment on the laminate to reduce resistance of at least a peripheral portion of a portion of the n-type semiconductor layer on a side of the active layer.

(40) The method for manufacturing a surface emitting laser according to any one of (25) to (39), in which the resonator includes a p-type semiconductor layer on a side of the active layer opposite to a side of the tunnel junction layer, and in the step of increasing the resistance, resistance of a peripheral portion of at least a portion of the p-type semiconductor layer on a side of the active layer is also increased.

(41) The surface emitting laser according to (1), in which the resonator includes a cladding layer between the tunnel junction layer and the active layer, and in the cladding layer, a central portion and a peripheral portion have lower resistance than a peripheral portion of the tunnel junction layer.

(42) The surface emitting laser according to (41), in which the cladding layer is an n-type semiconductor layer.

(43) The surface emitting laser according to (41) or (42), in which the cladding layer is constituted by an n-type InP compound semiconductor.

(44) The surface emitting laser according to any one of (41) to (43), in which in the active layer, at least a peripheral portion of a portion on a side of the tunnel junction layer has higher resistance than a central portion.

(45) The surface emitting laser according to any one of (41) to (44), in which the resonator includes another cladding layer on a side of the active layer opposite to a side of the tunnel junction layer, and in the another cladding layer, at least a peripheral portion of a portion on a side of the tunnel junction layer has higher resistance than a central portion.

(46) The surface emitting laser according to (45), in which an electrode is provided on the another cladding layer or a substrate disposed on a side of the another cladding layer opposite to a side of the tunnel junction layer.

(47) The surface emitting laser according to (45) or (46), in which the another cladding layer is a p-type semiconductor layer.

(48) The surface emitting laser according to any one of (45) to (47), in which the another cladding layer is constituted by a p-type InP compound semiconductor.

(49) The surface emitting laser according to any one of (41) to (48), in which the resonator includes further another cladding layer on a side of the tunnel junction layer opposite to a side of the active layer, and in the further another cladding layer, a central portion and a peripheral portion have lower resistance than a peripheral portion of the tunnel junction layer.

(50) The surface emitting laser according to (49), in which an electrode is provided on the further another cladding layer.

(51) The surface emitting laser according to (49) or (50), in which the further another cladding layer is an n-type semiconductor layer.

(52) The surface emitting laser according to any one of (49) to (51), in which the further another cladding layer is constituted by an n-type InP compound semiconductor.

(53) The surface emitting laser according to (1), in which the resonator includes a cladding layer between the tunnel junction layer and the active layer, and in the cladding layer, at least a peripheral portion of a portion on a side of the tunnel junction layer has higher resistance than a central portion.

(54) The surface emitting laser according to (53), in which the cladding layer is a p-type semiconductor layer.

(55) The surface emitting laser according to (53) or (54), in which the cladding layer is constituted by a p-type InP compound semiconductor.

(56) The surface emitting laser according to any one of (53) to (55), in which in the active layer, at least a peripheral portion of a portion on a side of the tunnel junction layer has higher resistance than a central portion.

(57) The surface emitting laser according to any one of (53) to (56), in which the resonator includes another cladding layer on a side of the active layer opposite to a side of the tunnel junction layer, and in the another cladding layer, a central portion and a peripheral portion have lower resistance than a peripheral portion of the tunnel junction layer.

(58) The surface emitting laser according to (57), in which an electrode is provided on the another cladding layer.

(59) The surface emitting laser according to (57) or (58), in which the another cladding layer is an n-type semiconductor layer.

(60) The surface emitting laser according to any one of (57) to (59), in which the another cladding layer is constituted by an n-type InP compound semiconductor.

(61) The surface emitting laser according to any one of (53) to (60), in which the resonator includes further another cladding layer on a side of the tunnel junction layer opposite to a side of the active layer, and in the further another cladding layer, at least a peripheral portion of a portion on a side of the tunnel junction layer has higher resistance than a (62) The surface emitting laser according to (61), in which an electrode is provided on the further another cladding layer or a substrate disposed on a side of the further another cladding layer opposite to a side of the tunnel junction layer.

(63) The surface emitting laser according to (61) or (62), in which the further another cladding layer is a p-type semiconductor layer.

(64) The surface emitting laser according to any one of (61) to (63), in which the further another cladding layer is constituted by a p-type InP compound semiconductor.

(65) A surface emitting laser including:
first and second reflectors; and
a resonator disposed between the first and second reflectors, the resonator including an active layer and a tunnel junction layer,
the resonator including:
a cladding layer disposed between the active layer and the tunnel junction layer;
another cladding layer disposed on a side of the active layer opposite to a side of the tunnel junction layer; and
further another cladding layer disposed on a side of the tunnel junction layer opposite to a side of the active layer,
in which, in the resonator, a peripheral portion has higher resistance than a central portion at least in an entire region in a thickness direction of the tunnel junction layer.

(66) The surface emitting laser according to (65), in which the cladding layer is a p-type semiconductor layer, and each of the another cladding layer and the further another cladding layer is an n-type semiconductor layer.

(67) The surface emitting laser according to (65), in which each of the cladding layer and the further another cladding layer is an n-type semiconductor layer, and the another cladding layer is a p-type semiconductor layer.

(68) The surface emitting laser according to (65),
in which each of the cladding layer and the further another cladding layer is a p-type semiconductor layer, and
the another cladding layer is an n-type semiconductor layer.

### REFERENCE SIGNS LIST

100, 100-1 to 100-5, 200, 200-1 to 200-5, 300, 300-1 to 300-4,
400 Surface emitting laser
101 Growth substrate (first substrate)
102 Second reflector
103 Second cladding layer (cladding layer)
104 Active layer
105 First cladding layer (cladding layer)
106 Tunnel junction layer
106a p-type semiconductor region
106b n-type semiconductor region
107 Third cladding layer (cladding layer)
108 First reflector
109 Anode electrode (electrode)
110 Cathode electrode
120 Support substrate
130 Substrate (second substrate)
1000 Distance measuring device (electronic device)

1. A surface emitting laser comprising:
first and second reflectors; and
a resonator disposed between the first and second reflectors, the resonator including an active layer and a tunnel junction layer,
wherein, in the resonator, a peripheral portion has higher resistance than a central portion at least in an entire region in a thickness direction of the tunnel junction layer.

2. The surface emitting laser according to claim 1,
wherein the resonator includes a cladding layer between the tunnel junction layer and the active layer, and
in the cladding layer, at least a peripheral portion of a portion on a side of the tunnel junction layer has higher resistance than a central portion.

3. The surface emitting laser according to claim 2, wherein the cladding layer is a p-type semiconductor layer.

4. The surface emitting laser according to claim 2, wherein the cladding layer is constituted by a p-type InP compound semiconductor.

5. The surface emitting laser according to claim 1, wherein in the active layer, at least a peripheral portion of a portion on a side of the tunnel junction layer has higher resistance than a

6. The surface emitting laser according to claim 1,
wherein the resonator includes a cladding layer on a side of the active layer opposite to a side of the tunnel junction layer, and
a central portion and a peripheral portion of the cladding layer have lower resistance than a peripheral portion of the tunnel junction layer.

7. The surface emitting laser according to claim 6, wherein an electrode is provided on the cladding layer.

8. The surface emitting laser according to claim 6, wherein the cladding layer is an n-type semiconductor layer.

9. The surface emitting laser according to claim 6, wherein the cladding layer is constituted by an n-type InP compound semiconductor.

10. The surface emitting laser according to claim 1,
wherein the resonator includes a cladding layer on a side of the tunnel junction layer opposite to a side of the active layer, and
a central portion and a peripheral portion of the cladding layer have lower resistance than a peripheral portion of the tunnel junction layer.

11. The surface emitting laser according to claim 10, wherein an electrode is provided on the cladding layer.

12. The surface emitting laser according to claim 10, wherein the cladding layer is an n-type semiconductor layer.

13. The surface emitting laser according to claim 10, wherein the cladding layer is constituted by an n-type InP compound semiconductor.

14. The surface emitting laser according to claim 1, wherein a peripheral portion of the resonator is increased in resistance by ion implantation at least in an entire region in a thickness direction of the tunnel junction layer.

15. The surface emitting laser according to claim 14, wherein an impurity concentration in the ion implantation is less than 1×10¹⁹ cm⁻³.

16. The surface emitting laser according to claim 14, wherein impurity in the ion implantation includes at least one of H, B, C, or O.

17. The surface emitting laser according to claim 1,
wherein the tunnel junction layer includes a p-type semiconductor region and an n-type semiconductor region, and
each of the p-type semiconductor region and the n-type semiconductor region is constituted by any of an InP-based compound semiconductor, an AlGaInAs-based compound semiconductor, and an AlGaInSbAs-based compound semiconductor body.

18. The surface emitting laser according to claim 1, further comprising
a substrate disposed between the resonator and a reflector closer to the active layer than the tunnel junction layer among the first and second reflectors,
wherein the reflector is a concave multilayer film reflector.

19. The surface emitting laser according to claim 18, wherein a thermal conductivity of the substrate is 40 W/m·K or more.

20. An electronic device comprising the surface emitting laser according to claim 1.
